(19) United States
(12) Patent Application Publication
(10) Pub. No.: US 2007/0274814 A1
(43) Pub. Date: Nov. 29, 2007

(54) Local clean robot-transport plant and robot-transport manufacturing method

(76) Inventors: Atsuko Kawasaki, Kanagawa-ken (JP); Masahiro Kiyotoshi, Kanagawa-ken (JP); Shoko Ito, Kanagawa-ken (JP); Makiko Katano, Kanagawa-ken (JP); Ayako Mizuno, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/797,528

(22) Filed: May 4, 2007

(30) Foreign Application Priority Data
May 26, 2006 (JP) 2006-146990

(51) Int. Cl. H01L 21/677

(52) U.S. Cl. 414/217.1

(57) ABSTRACT

A local clean robot-transport plant includes: a plurality of manufacturing apparatuses; a plurality of closed-type transport containers; a container discrimination/selection apparatus; an apparatus group control server. Each of the plurality of closed-type transport containers stores and transports an intermediate product of manufacturing processes along a plurality of interprocess transport paths defined among the plurality of manufacturing apparatuses in accordance with a flow of the manufacturing processes. The container discrimination/selection apparatus is configured to discriminate and select the closed-type transport container of transport type 1 and the closed-type transport container of transport type 2, respectively, from among the plurality of closed-type transport containers. The apparatus group control server is configured to collectively control operation of the plurality of manufacturing apparatuses and the container discrimination/selection apparatus to move the closed-type transport container of transport type 2 to a specific interprocess transport path and to move the closed-type transport container of transport type 1 to the interprocess transport path other than the specific interprocess transport path.

### CROSS-REFERENCE TO RELATED APPLICATIONS

This application is based upon and claims the benefit of priority from the prior Japanese Patent Application No. 2006-146990, filed on May 26, 2006; the entire contents of which are incorporated herein by reference.

### BACKGROUND OF THE INVENTION

1. Field of the Invention

This invention relates to a local clean robot-transport plant where closed-type transport containers are transported to realize a minienvironment, and a robot-transport manufacturing method implemented thereby.

2. Background Art

There is an ongoing transition from 200-mm to 300-mm wafers for increasing the chip yield per wafer. Conventional manufacturing of industrial products requiring cleanliness is based on methods using a clean room. However, products such as LSIs, which are downscaled to enhance their commercial value, require higher cleanliness as the downscaling advances. Failure to improve cleaning performance decreases the product yield rate and profit. Furthermore, the enormous cost of constructing and operating the clean room for enhancing cleanliness also directly leads to profit decrease. Up to the 200-mm wafer generation, the clean room is entirely cleaned by downflow. However, the amount of capital investment in such super clean technology is becoming enormous. In the 300-mm era, the minienvironment approach is going mainstream, where the local space around the wafer is thoroughly cleaned.

The minienvironment approach is the antithesis of the super clean technology. The minienvironment approach is a local clean technology where about 25 semiconductor wafers in a box is placed in a closed-type wafer transport container called FOUP (Front Opening Unified Pod), and an especially clean environment is made only in the FOUP. Thus the trend is shifting to reducing the operating cost as well as the initial investment (see U.S. Pat. No. 4,532,970).

The “FOUP” is a transport container for 300-mm wafers, which is compliant with SEMI (Semiconductor Equipment and Materials Institute) standards. The FOUP is a closed pod where cleanliness comparable to that in the minienvironment system can be maintained. The FOUP is used for robot-transporting semiconductor wafers from the minienvironment of one process to that of another process, or for automatically exchanging semiconductor wafers with a semiconductor manufacturing apparatus.

However, because the FOUP is a closed container, cross-contamination by contaminants (contaminating factors) via FOUP materials may cause the stoppage of the production line and/or decrease the yield, presenting a serious problem in managing the process of manufacturing semiconductor devices.

Currently, besides semiconductor device manufacturing, the minienvironment system based on closed containers typified by FOUPs is also drawing attention in the fields of liquid crystal devices such as flat panel displays (FPDs) and recording media such as hard disks. The above problem is also serious in robot-transport manufacturing techniques in these other technical fields.

### SUMMARY OF THE INVENTION

According to an aspect of the invention, there is provided a local clean robot-transport plant including: a plurality of manufacturing apparatuses; a plurality of closed-type transport containers, each closed-type transport container storing and transporting an intermediate product of manufacturing processes along a plurality of interprocess transport paths defined among the plurality of manufacturing apparatuses in accordance with a flow of the manufacturing processes; a container discrimination/selection apparatus configured to discriminate and select the closed-type transport container of transport type 1 and the closed-type transport container of transport type 2, respectively, from among the plurality of closed-type transport containers; an apparatus group control server configured to collectively control operation of the plurality of manufacturing apparatuses and the container discrimination/selection apparatus to move the closed-type transport container of transport type 2 to a specific interprocess transport path and to move the closed-type transport container of transport type 1 to the interprocess transport path other than the specific interprocess transport path.

According to another aspect of the invention, there is provided a robot-transport manufacturing method based on a plurality of manufacturing apparatuses controlled by an apparatus group control server, an intermediate product of manufacturing processes being stored in a plurality of closed-type transport containers and transported along a plurality of interprocess transport paths defined among the plurality of manufacturing apparatuses in accordance with a flow of the manufacturing processes, the method including: under control of the apparatus group control server, using the closed-type transport container of transport type 2 only on a specific interprocess transport path, and using only the closed-type transport container of transport type 1 on the interprocess transport paths other than the specific interprocess transport path.

According to another aspect of the invention, there is provided a robot-transport manufacturing method configured to manufacture intended industrial products, an intermediate product of manufacturing processes being stored in closed-type transport containers and transported along a plurality of interprocess transport paths defined among a plurality of manufacturing apparatuses in accordance with a flow of the manufacturing processes, the method including: using the closed-type transport container of transport type 2 only on a specific interprocess transport path; and using only the closed-type transport container of transport type 1 on the interprocess transport paths other than the specific interprocess transport path.

### BRIEF DESCRIPTION OF THE DRAWINGS

FIG. 1 is a plan view schematically illustrating a local clean robot-transport plant according to an embodiment of the invention.

FIG. 2A is a perspective view of a closed-type transport container according to the embodiment of the invention where its front-opening lid is opened, and FIG. 2B is a perspective view of the closed-type transport container according to the embodiment of the invention where its front-opening lid is closed.

FIG. 3A is a plan view schematically illustrating a basic configuration of a minienvironment system used in the local clean robot-transport plant according to the embodiment of the invention with reference to a particular semiconductor manufacturing apparatus, and FIG. 3B is a corresponding side view.

FIG. 4 schematically illustrates a procedure of inspecting cross-contamination of closed-type transport containers caused by polysilazane (PSZ) film using a closed-type transport container (FOUP) 1 shown in FIG. 4A, a closed-type transport container (FOUP) 2 shown in FIG. 4B, and a closed-type transport container (FOUP) 3 shown in FIG. 4C.

FIG. 5A is a schematic cross-sectional view of a pattern of a photoresist film in the non-contaminated condition, and FIG. 5B is a schematic cross-sectional view illustrating a defective shape called “skirt” caused by cross-contamination.

FIG. 6 is a block diagram showing a logical circuit configuration of a semiconductor memory device (nonvolatile semiconductor memory device, or NAND flash memory) according to the embodiment of the invention.

FIG. 7 is a schematic plan view showing a physical layout pattern configuration of part of a memory cell array of the semiconductor memory device shown in FIG. 6.

FIG. 8 is a cross-sectional view showing part (NAND cell column) of the memory cell array cut along the bit line (A-A direction) in FIG. 7.

FIGS. 9 to 22 are process cross-sectional views for illustrating a robot-transport manufacturing method according to the embodiment of the invention by way of an example method for manufacturing a semiconductor memory device (nonvolatile semiconductor memory device), where FIGS. 9 to 18 are taken parallel to the word line in FIG. 7, and FIGS. 19 to 22 are taken parallel to the bit line in FIG. 7.

### DETAILED DESCRIPTION OF THE INVENTION

Embodiments of the invention will now be described with reference to the drawings. In the following description of the figures, like or similar elements are marked with like or similar reference numerals. However, the figures are schematic. It should be noted that the relation of the thickness to the planar dimension and the ratio of thickness between various layers may be different from reality. Therefore the specific thickness or dimension should be determined by taking the following description into consideration. It is also understood that the dimensional relationship and/or ratio may be varied between some of the figures.

The embodiments described herein are illustrated with reference to a method for manufacturing a semiconductor device (semiconductor memory device). However, it is understood that the invention is applicable to robot-transport manufacturing methods in technical fields requiring cleanliness such as liquid crystal devices, magnetic recording media, optical recording media, thin-film magnetic heads, and superconducting devices. That is, the following embodiments illustrate facilities, apparatuses, and methods for embodying the technical spirit according to the local clean robot-transport plant and robot-transport manufacturing method of the invention. The spirit of the invention does not limit the contaminating factors responsible for cross-contamination, the material, shape, and structure of the components of the closed-type transport container, and the layout of the robot-transport plant to those described in the following embodiments.

Local Clean Robot-Transport Plant

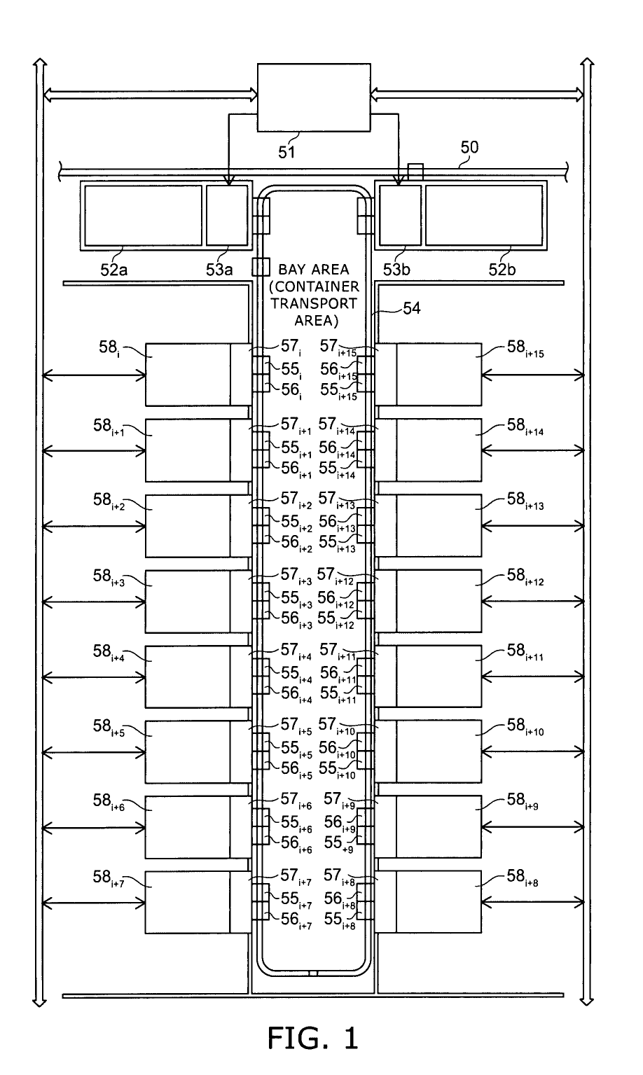

As shown in FIG. 1, the local clean robot-transport plant according to the embodiment of the invention comprises a plurality of manufacturing apparatuses 58ᵢ, 58ᵢ₊₁, 58ᵢ₊₂, 58ᵢ₊₃, . . . required for manufacturing intended industrial products, temporary container cabinets 52a, 52b for storing a plurality of closed-type transport containers that store and transport intermediate products of manufacturing processes along a plurality of interprocess transport paths defined among the plurality of manufacturing apparatuses 58ᵢ, 58ᵢ₊₁, 58ᵢ₊₂, 58ᵢ₊₃, . . . in accordance with the flow of the manufacturing processes of the industrial products, container discrimination/selection apparatuses 53a, 53b for discriminating and selecting a closed-type transport container of transport type 1 and a closed-type transport container of transport type 2, respectively, from among the plurality of closed-type transport containers stored in the temporary container cabinets 52a, 52b, and an apparatus group control server 51 for collectively controlling the operation of the plurality of manufacturing apparatuses 58ᵢ, 58ᵢ₊₁, 58ᵢ₊₂, 58ᵢ₊₃, . . . and the container discrimination/selection apparatuses 53a, 53b to move the closed-type transport container of transport type 2 to a specific interprocess transport path and to move the closed-type transport container of transport type 1 to a non-specific interprocess transport path (i.e. an interprocess transport path other than the specific interprocess transport path).

The “interprocess transport path” used herein refers to a logical transport path defined among a plurality of processes arranged in time series. Hence actual mechanical (physical) transport paths may partially or entirely overlap each other because in some cases (situations), the same manufacturing apparatus is used in a plurality of different processes.

The “specific interprocess transport path” used herein refers to an interprocess transport path having a specific problem and/or purpose such as cross-contamination via a closed-type transport container caused by contaminating factors due to a specific process. The “specific interprocess transport path” is predetermined on the basis of preliminary experiments or other empirical rules before starting manufacturing processes for industrial products. Here, the contaminating factors do not necessarily need to be identified, but the “specific interprocess transport path” can be determined on the basis of experimental facts of cross-contamination, which will be described later. Contaminating factors include organic and inorganic contaminants, and may also include organisms such as bacteria in the case of biotechnology or pharmaceutical manufacturing. Conversely, the “interprocess transport path having a specific purpose” refers to the case having such a purpose as intentional doping with specific impurities or intentional introduction of different chemicals to compensate for contamination by other contaminants.

As shown in FIG. 1, the local clean robot-transport plant according to the embodiment of the invention further comprises a transport rail 54 where the closed-type transport containers storing intermediate products of the industrial products can be robot-transported between the container discrimination/selection apparatuses 53a, 53b and the manufacturing apparatuses 58ᵢ, 58ᵢ₊₁, 58ᵢ₊₂, 58ᵢ₊₃, . . . , and along the interprocess transport paths defined among the manufacturing apparatuses 58ᵢ, 58ᵢ₊₁, 58ᵢ₊₂, 58ᵢ₊₃, . . . .

The local clean robot-transport plant according to the embodiment of the invention does not need to include all the manufacturing apparatuses required for manufacturing the intended industrial products. Part of the processes may be assigned to other local clean robot-transport plants. As described above, the “interprocess transport path” is defined as a logical transport path. Hence, when part of the processes are assigned to other local clean robot-transport plants, the transport rail 54 shown in FIG. 1 may include portions that do not correspond to any interprocess transport paths among the manufacturing apparatuses 58ᵢ, 58ᵢ₊₁, 58ᵢ₊₂, 58ᵢ₊₃, . . . .

Although not shown, the local clean robot-transport plant according to the embodiment of the invention may also include, besides the bay area shown in FIG. 1, another bay area and/or building, where other manufacturing apparatuses may be located. There may be a plurality of bay areas and/or buildings. Thus, as shown at the top of FIG. 1, the local clean robot-transport plant according to the embodiment of the invention includes an interbay container transport rail 50, which is connected to other transport rails (second transport rail, third transport rail, fourth transport rail, . . . ) for other manufacturing apparatuses located in other bay areas (second bay area, third bay area, fourth bay area, . . . ), not shown.

There may be a plurality of closed-type transport containers of “transport type 1” and closed-type transport containers of “transport type 2”. Furthermore, within the range of standards satisfying a prescribed level, the inner wall treatment (inner wall structure) of the closed-type transport container of “transport type 1” may be different from the inner wall treatment (inner wall structure) of the closed-type transport container of “transport type 2”.

Under commands from the apparatus group control server 51, the container discrimination/selection apparatuses 53a, 53b discriminate between closed-type transport containers of “transport type 1” and “transport type 2”, select a closed-type transport container for use between each pair of processes, and send it out to the transport rail 54. The transport rail 54 circumscribes the bay area (container transport area), and the manufacturing apparatuses 58ᵢ, 58ᵢ₊₁, 58ᵢ₊₂, 58ᵢ₊₃, . . . are connected to the transport rail 54 through associated transfer chambers (apparatus front chambers) 57ᵢ, 57ᵢ₊₁, 57ᵢ₊₂, 57ᵢ₊₃, . . . , respectively.

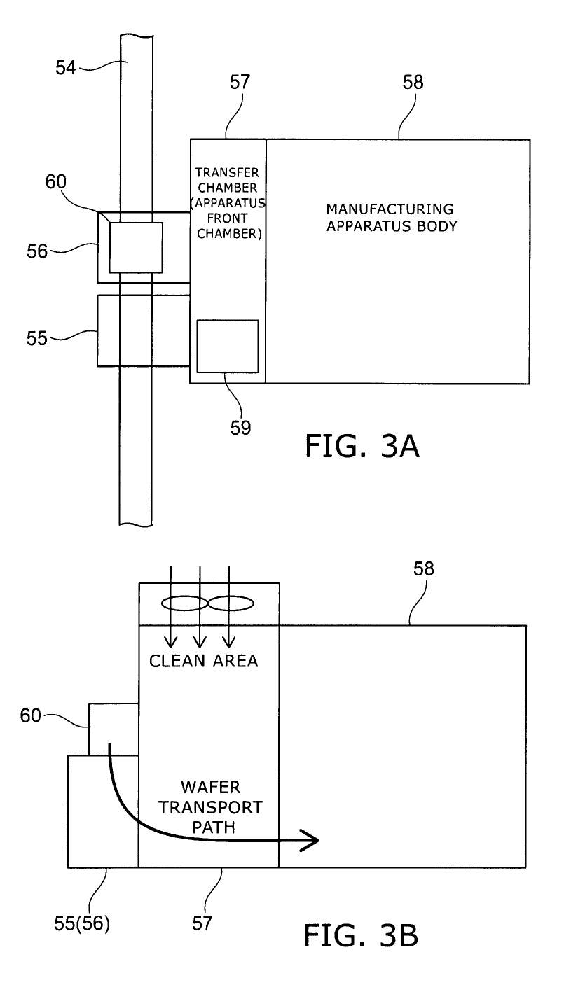

More specifically, as shown in FIG. 1, the local clean transfer chamber (apparatus front chamber) 57ᵢ, 57ᵢ₊₁, 57ᵢ₊₂, 57ᵢ₊₃, . . . is provided with a container passing mechanism for loading (loader) 55ᵢ, 55ᵢ₊₁, 55ᵢ₊₂, 55ᵢ₊₃, . . . and a container passing mechanism for unloading (unloader) 56ᵢ, 56ᵢ₊₁, 56ᵢ₊₂, 56ᵢ₊₃, . . . connected to the transport rail 54 (see FIG. 3 in detail). In the container passing mechanism for loading (loader) 55ᵢ, 55ᵢ₊₁, 55ᵢ₊₂, 55ᵢ₊₃, . . . , the lid of the closed-type transport container is automatically opened, intermediate products are transferred from the closed-type transport container through the local clean transfer chamber (apparatus front chamber) 57ᵢ, 57ᵢ₊₁, 57ᵢ₊₂, 57ᵢ₊₃, . . . to the associated manufacturing apparatus 58ᵢ, 58ᵢ₊₁, 58ᵢ₊₂, 58ᵢ₊₃, . . . , where the treatment of a prescribed process is performed. Upon completion of the treatment of the process, the intermediate products are transferred to the container passing mechanism for unloading (unloader) 56ᵢ, 56ᵢ₊₁, 56ᵢ₊₂, 56ᵢ₊₃, . . . through the associated transfer chamber (apparatus front chamber) 57ᵢ, 57ᵢ₊₁, 57ᵢ₊₂, 57ᵢ₊₃, . . . Inside the container passing mechanism for unloading (unloader) 56ᵢ, 56ᵢ₊₁, 56ᵢ₊₂, 56ᵢ₊₃, . . . , the intermediate products are automatically stored. Furthermore, the lid of the closed-type transport container is automatically closed. Then the closed-type transport container is robot-transported to the apparatus of the next process via the transport rail 54.

The apparatus group control server 51 shown in FIG. 1 can serve as a manufacturing execution system (MES) server, which makes it possible to construct a group of systems for plant management interconnecting the enterprise resource planning (ERP) package, which is a business-oriented system used at the headquarter, and a group of control-oriented systems for operating machines at the manufacturing site. Hence, as shown in FIG. 1, the plurality of manufacturing apparatuses 58ᵢ, 58ᵢ₊₁, 58ᵢ₊₂, 58ᵢ₊₃, . . . , the apparatus group control server 51, and the container discrimination/selection apparatuses 53a, 53b may be connected to each other through any communication network (LAN of MES). The apparatus group control server 51 serving as a MES server transmits, to the plurality of manufacturing apparatuses 58ᵢ, 58ᵢ₊₁, 58ᵢ₊₂, 58ᵢ₊₃, . . . , instructions for specific treatments (instructions for jobs), and simultaneously, instructions as to which of the closed-type transport container of transport type 2 and the closed-type transport container of transport type 1 is to be used as the closed-type transport container for transporting intermediate products between each pair of apparatuses. A single apparatus group control server 51 is shown in FIG. 1, but this is for illustrative purpose only. It is understood that a plurality of apparatus group control servers may be physically located through the communication network (LAN of MES) 19.

FIG. 1 illustratively shows a local clean robot-transport plant intended for a semiconductor plant. For this reason, FIG. 1 shows a configuration comprising a washer 58ᵢ for washing the surface of a semiconductor wafer, which is an intermediate product, or removing resist therefrom with acid solution or pure water, a gate oxidation (thermal oxidation) apparatus 58ᵢ₊₁ for forming thin silicon oxide film (SiO₂ film) such as tunnel oxide film, a polysilicon reduced-pressure chemical vapor deposition (CVD) apparatus 58ᵢ₊₂ for depositing polysilicon film, a nitride film reduced-pressure CVD apparatus 58ᵢ₊₃ for depositing silicon nitride film (Si₃N₄ film), a spin coater (spinner) 58ᵢ₊₄ for spin coating photoresist film, a stepper (exposure apparatus) 58ᵢ₊₅ for patterning photoresist film by exposure thereof using photolithography to transfer a desired pattern, a developing apparatus 58ᵢ₊₆ for developing exposed photoresist film, a reactive ion etching (RIE) apparatus 58ᵢ₊₇ for etching thin film formed in or on the surface of an intermediate product (semiconductor wafer), a silazane perhydride coater 58ᵢ₊₈ for applying silazane perhydride, a silazane perhydride baking apparatus 58ᵢ₊₉ for heat treating the applied silazane perhydride to form polysilazane (PSZ) film, a PSZ film oxidation apparatus 58ᵢ₊₁₀ for oxidizing PSZ film, a chemical mechanical polishing (CMP) apparatus 58ᵢ₊₁₁ for polishing the surface of an intermediate product (semiconductor wafer), an interelectrode insulating film reduced-pressure CVD apparatus 58ᵢ₊₁₂ for depositing interelectrode insulating film, e.g. silicon nitride film (Si₃N₄ film), strontium oxide (SrO) film, aluminum oxide (Al₂O₃) film, magnesium oxide (MgO) film, yttrium oxide (Y₂O₃) film, hafnium oxide (HfO₂) film, zirconium oxide (ZrO₂) film, tantalum oxide (Ta₂O₅) film, and bismuth oxide (Bi₂O₃) film, and ternary compound insulating film such as hafnium aluminate (HfAlO) film, an ion implantation apparatus 58ᵢ₊₁₃ for implanting desired dopant ions into an intermediate product (semiconductor wafer), an annealing furnace 58ᵢ₊₁₄ for heat treating an intermediate product (semiconductor wafer) after ion implantation to activate implanted ions, and an interlayer insulating film CVD apparatus 58ᵢ₊₁₅ for depositing interlayer insulating film such as SiO₂ film, phosphosilicate glass (PSG) film, borosilicate glass (BSG) film, borophosphosilicate glass (BPSG) film, and silicon nitride film (Si₃N₄ film). These apparatuses are arranged so that the associated local clean transfer chambers (apparatus front chambers) 57ᵢ, 57ᵢ₊₁, 57ᵢ₊₂, 57ᵢ₊₃, . . . surround the bay area. However, the arrangement of FIG. 1 is a schematic illustration, and the arrangement is not limited thereto. For example, a plurality of ion implantation apparatuses 58ᵢ₊₁₃ may be provided for different dopant ions, dose amounts, and intended processes. Similarly, a plurality of RIE apparatuses 58ᵢ₊₇ may be provided for different objects to be etched, and it is more advantageous for ease of maintenance. On the other hand, if Si₃N₄ film is used as interelectrode insulating film, the interelectrode insulating film reduced-pressure CVD apparatus 58ᵢ₊₁₂ may be replaced by the nitride film reduced-pressure CVD apparatus 58ᵢ₊₃, and the interelectrode insulating film reduced-pressure CVD apparatus 58ᵢ₊₁₂ may be omitted.

The spinner 58ᵢ₊₄, the stepper 58ᵢ₊₅, and the developing apparatus 58ᵢ₊₆, which are related to photolithography, may be streamlined into a continuous process line having a clean area for internal transport. A common container passing mechanism for loading (loader) and container passing mechanism for unloading (unloader) may be provided, respectively, at the inlet and outlet of this process line to form an integrated manufacturing apparatus. Similarly, the silazane perhydride coater 58ᵢ₊₈, the silazane perhydride baking apparatus 58ᵢ₊₉, and the PSZ film oxidation apparatus 58ᵢ₊₁₀ may be streamlined into a continuous process line having a clean area for internal transport, and a common loader and unloader may be provided, respectively, at the inlet and outlet of this process line to form an integrated manufacturing apparatus.

It is understood that, in addition to the configuration shown in FIG. 1, the plant may include various semiconductor manufacturing apparatuses such as a wet etching apparatus for etching the surface of an intermediate product (semiconductor wafer) with etching liquid, a dopant diffusion apparatus for diffusing dopant elements from vapor phase into an intermediate product (semiconductor wafer), a heat treatment apparatus for reflowing (melting) PSG film, BSG film, or BPSG film, a heat treatment apparatus for densifying CVD oxide film, a heat treatment apparatus for forming silicide film, a sputtering apparatus for depositing a metal interconnect layer, a vacuum evaporation apparatus, a plating apparatus for further forming a metal interconnect layer by plating, a dicer, and a bonder for connecting the electrode of a diced semiconductor device chip to a lead frame. In this connection, an interbay container transport rail 50 is shown at the top of FIG. 1. These various manufacturing apparatuses may be located in a region around another bay area or in another building. The plurality of manufacturing apparatuses 58ᵢ, 58ᵢ₊₁, 58ᵢ₊₂, 58ᵢ₊₃, . . . may be intended for either batch processing or single-wafer processing.

The local clean robot-transport plant according to the embodiment of the invention may also include various inspection and measurement apparatuses such as an interferometric thickness gauge, ellipsometer, contact thickness gauge, microscope, and resistance measurement apparatus. Furthermore, although irrelevant to the transport of intermediate products by closed-type transport containers, it is understood that the local clean robot-transport plant may also include ancillary facilities such as a pure water producer and gas purifier.

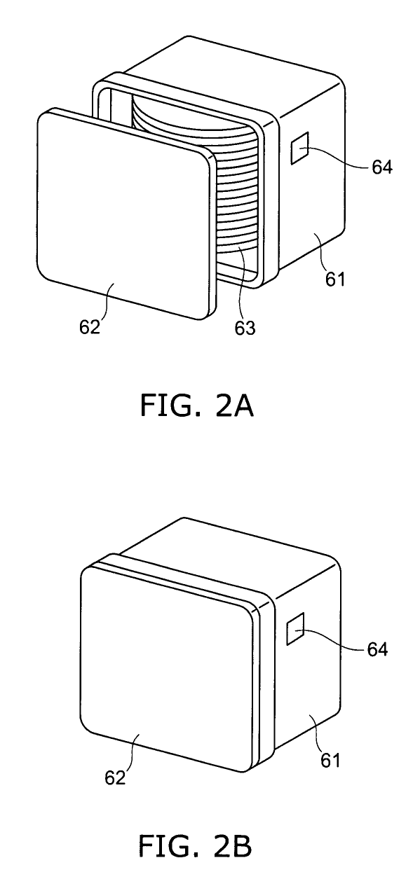

FIG. 2 is a schematic view showing a closed-type transport container, which is intended to serve as a front opening unified pod (FOUP) for 300-mm wafers compliant with SEMI standards. However, it is not necessarily limited to the FOUP. For example, it may be a closed-type transport container for 200-mm wafers compliant with SEMI standards, called SMIF (Standard of Mechanical Interface) pod. The SMIF pod is designed for vertical loading with internal wafer trays, whereas the FOUP is designed for horizontal loading without wafer trays. It is to be noted that, irrespective of this difference, the closed-type transport container according to the embodiment of the invention refers to a concept encompassing FOUPs, SMIF pods, and similar containers compliant with the local clean technology that can be robot-transported and automatically opened and closed. However, the closed-type transport container according to the embodiment of the invention is more advantageous for containers without wafer trays rather than for containers having internal wafer trays. Furthermore, the closed-type transport container may be equipped with a purge line for high-purity nitrogen (N₂) or other gas.

An RF tag serving as a “container identification information output means” intended for identifying a closed-type transport container is attached to the container body 61 of the closed-type transport container according to the embodiment of the invention. FIG. 2A shows the closed-type transport container where its front-opening lid 62 is opened, and 24 intermediate products (semiconductor wafers) are stored inside the container body 61 using grooves (slots) cut inside the container body 61. On the other hand, FIG. 2B shows the closed state of the closed-type transport container where its front-opening lid 62 is closed.

The RF tag (container identification information output means) 64 attached to the side face of the container body 61 is populated with container identification information including at least the container number and the type identification information that identifies whether the closed-type transport container is of transport type 2 defined for specific interprocess transport paths or of transport type 1 used on the other interprocess transport paths. Furthermore, product information concerning intermediate products (semiconductor wafers) stored in the closed-type transport container may be also recorded in the RF tag 64, such as the product name, process name, lot number, and the intermediate product numbers of intermediate products included in the lot, and thereby the history of the closed-type transport container may be added to the container identification information.

The container identification information output means is not limited to the RF tag 64, but various two-dimensional codes such as Data Matrix, QR Code, PDF417, Maxi Code, and Veri Code can be used. Furthermore, it is possible to use various codes such as alphanumeric or other character codes other than two-dimensional codes, graphics, one-dimensional codes, and combined graphic codes of one-dimensional and two-dimensional codes. It is also possible to use intermediate codes between one-dimensional and two-dimensional codes such as the stacked barcode, which is made of barcodes (one-dimensional codes) stacked two-dimensionally (however, two-dimensional codes are more preferable in terms of the amount of information per unit area).

The closed-type transport container shown in FIG. 2 is a schematic example. The attaching position of the container identification information output means such as the RF tag 64 or the two-dimensional code equivalent to the RF tag 64 does not need to be the side face as shown in FIG. 2, but may be the back, top, or bottom face of the container body 61. That is, the position may be anywhere as long as a host device (container identification information input means) such as an RF tag receiver or an image sensor for reading the two-dimensional code can read the container identification information.

In FIG. 3, a particular set of the manufacturing apparatus 58ᵢ, 58ᵢ₊₁, 58ᵢ₊₂, 58ᵢ₊₃, . . . , transfer chamber (apparatus front chamber) 57ᵢ, 57ᵢ₊₁, 57ᵢ₊₂, 57ᵢ₊₃, . . . , container passing mechanism for loading (loader) 55ᵢ, 55ᵢ₊₁, 55ᵢ₊₂, 55ᵢ₊₃, . . . , and container passing mechanism for unloading (unloader) 56ᵢ, 56ᵢ₊₁, 56ᵢ₊₂, 56ᵢ₊₃, . . . shown in FIG. 1 is selected as a representative and generically shown as a manufacturing apparatus (manufacturing apparatus body) 58, a transfer chamber (apparatus front chamber) 57, a container passing mechanism for loading (loader) 55, and a container passing mechanism for unloading (unloader) 56. The transfer chamber (apparatus front chamber) 57 locally cleaned as a clean area is equipped with an RF tag receiver 59 serving as a “container identification information input means” for receiving signals from the RF tag (container identification information output means) 64 shown in FIG. 2. The RF tag receiver (container identification information input means) 59 may be installed on the container passing mechanism for loading (loader) 55 and the container passing mechanism for unloading (unloader) 56 rather than on the transfer chamber (apparatus front chamber) 57. When a two-dimensional code is used instead of the RF tag 64, a two-dimensional code reader serving as the container identification information input means may be installed on the container passing mechanism for loading (loader) 55 and the container passing mechanism for unloading (unloader) 56.

Lot Processing by Automatic Transport

An example lot processing by automatic transport in the local clean robot-transport plant according to the embodiment of the invention can be schematically described as follows with reference to the manufacturing apparatus (manufacturing apparatus body) 58 shown in FIG. 3 (as described above, the manufacturing apparatus 58 may be one of various manufacturing apparatuses 58ᵢ, 58ᵢ₊₁, 58ᵢ₊₂, 58ᵢ₊₃, . . . required for manufacturing intended industrial products (semiconductor devices) and inline inspection thereof, including lithography, etching, heat treatment, ion implantation, CVD, sputtering, evaporation, and washing, as described with reference to FIG. 1):

(a) First, upon receiving a lot processing instruction command from the apparatus group control server 51 shown in FIG. 1, the manufacturing apparatus (manufacturing apparatus body) 58 generates a processing instruction unit called “job” and communicates it to the apparatus group control server 51. The processing instruction unit is labeled with a job ID number (hereinafter referred to as “job identification number”) generated by the apparatus group control server 51. The apparatus group control server 51 hereafter performs progress management on lots by the job identification number reported from the manufacturing apparatus 58 (compliant with the SEMI standards).

(b) Upon receiving the notification from the manufacturing apparatus 58 that the manufacturing apparatus 58 has generated a job, the apparatus group control server 51 uses the job identification number to recognize product information such as the product name, process name, lot number, and the intermediate product numbers of intermediate products included in the lot. Furthermore, from the product information, the apparatus group control server 51 generates container information concerning the closed-type transport container 60 corresponding to the manufacturing apparatus 58 and communicates it to the manufacturing apparatus 58.

(c) Upon notification of the container information from the apparatus group control server 51 to the manufacturing apparatus 58, the RF tag receiver (container identification information input means) 59 installed on the transfer chamber (apparatus front chamber) 57 locally cleaned as a clean area reads a signal (container identification information) from the RF tag (container identification information output means) 64 provided on the closed-type transport container 60 and determines whether the closed-type transport container 60 transported via the transport rail 54 to the container passing mechanism for loading (loader) 55 has a correct transport type. That is, the signal (container identification information) from the RF tag 64 is used for checking the transport type to determine whether the closed-type transport container 60 is a closed-type transport container of transport type 2 or of transport type 1 which is to be transported between the process of the manufacturing apparatus 58 in question and the immediately preceding process. If it is determined that the transport type is correct, the lid of the closed-type transport container 60 is automatically opened in the container passing mechanism for loading (loader) 55, and intermediate products are transferred from the closed-type transport container 60 to the manufacturing apparatus 58 through the transfer chamber (apparatus front chamber) 57 locally cleaned as a clean area. If it is determined that the transport type of the closed-type transport container 60 is not correct, a notification of “type rejected” is communicated to the apparatus group control server 51. Then the apparatus group control server 51 performs an alarm handling by transmitting a command for stopping the operation (shutdown) of the manufacturing apparatus 58, and reports it to the process administrator and plant administrator, thereby canceling the processing of the lot.

(d) If it is determined that the transport type of the closed-type transport container 60 is correct, the manufacturing apparatus 58 starts an associated lot processing such as lithography, etching, heat treatment, ion implantation, CVD, sputtering, evaporation, and washing in accordance with a prescribed recipe. The prescribed recipe is managed by the apparatus group control server 51 shown in FIG. 1.

(e) While the manufacturing apparatus 58 is performing the associated lot processing in accordance with the prescribed recipe, the apparatus group control server 51 uses the product information to derive the process following the current processing of the manufacturing apparatus 58, generates container information concerning the type of the closed-type transport container 60 used in transporting intermediate products to the manufacturing apparatus of the next process, and communicates it to the manufacturing apparatus 58. If the transport to the next process involves no type change for the closed-type transport container 60, the empty closed-type transport container 60 is moved from the container passing mechanism for loading (loader) 55 to the container passing mechanism for unloading (unloader) 56 and waits until the processing of the prescribed process of the manufacturing apparatus 58 is completed.

(f) On the other hand, if the transport of intermediate products to the next process involves any type change for the closed-type transport container 60, the empty closed-type transport container 60 is transported from the container passing mechanism for loading (loader) 55 via the transport rail 54 to the container discrimination/selection apparatus 53a, 53b shown in FIG. 1. The container discrimination/selection apparatus 53a, 53b uses the signal (container identification information) from the RF tag 64 to select, in the temporary container cabinet 52a, 52b shown in FIG. 1, a closed-type transport container 60 of the transport type to be used in transporting intermediate products to the next process. That is, under the command from the apparatus group control server 51, the container discrimination/selection apparatus 53a, 53b selects a closed-type transport container 60 of transport type 1 or 2 and moves the selected closed-type transport container 60 to the container passing mechanism for unloading (unloader) 56 via the transport rail 54. Upon completion of the movement, the RF tag receiver 59 installed on the transfer chamber (apparatus front chamber) 57 uses the signal (container identification information) from the RF tag 64 to confirm whether the new closed-type transport container 60 transported to the container passing mechanism for unloading (unloader) 56 is a closed-type transport container 60 of the correct transport type to be used in transporting intermediate products to the next process. If it is confirmed that the transport type is correct, the closed-type transport container 60 waits until the ongoing processing of the manufacturing apparatus 58 is completed. If the transport type is rejected in the confirmation, a notification of “type rejected” is communicated to the apparatus group control server 51, and the closed-type transport container is returned to the container discrimination/selection apparatus 53a, 53b via the transport rail 54 again. The signal (container identification information) from the RF tag 64 is used to reselect another closed-type transport container, and simultaneously the reselection is communicated to the plant administrator.

(g) When the processing of the prescribed process is completed by the manufacturing apparatus 58 in accordance with the recipe, the resulting intermediate products are transferred to the container passing mechanism for unloading (unloader) 56 through the transfer chamber (apparatus front chamber) 57 locally cleaned as a clean area. Inside the container passing mechanism for unloading (unloader) 56, the intermediate products are automatically stored in the closed-type transport container 60. The lid of the closed-type transport container 60 is automatically closed. Then, under the command from the apparatus group control server 51, the closed-type transport container 60 is robot-transported via the transport rail 54 to the container passing mechanism for loading (loader) of the manufacturing apparatus of the next process.

In the foregoing method, while the manufacturing apparatus 58 is performing the processing of an associated process, the apparatus group control server generates container information concerning the type of the closed-type transport container 60 used in transporting intermediate products to the manufacturing apparatus of the next process. However, this is for illustrative purpose only. For example, before starting the lot processing, the container information for all the interprocess transport paths may be predetermined. The transport type of the closed-type transport container for every interprocess transport path may be preprogrammed on the basis of the predetermined container information, and the program may be stored in a program memory device. The closed-type transport containers 60 may be successively exchanged under the program stored in the program memory device.

Cross-Contamination Via a Closed-Type Transport Container Due to PSZ Film: Case 1

The shallow trench isolation (STI) structure is widely used for device isolation in semiconductor devices. In this structure, a groove is formed in the device isolation region of the semiconductor substrate, and silicon oxide (SiO₂) film or the like serving as device isolation insulating film is buried in this groove. With the downscaling of semiconductor devices, the aspect ratio of the groove increases, which makes it difficult to fill the STI groove with the conventional ozone (O₃)/tetraethylorthosilicate (TEOS) CVD oxide (SiO₂) film or high-density plasma (HDP) CVD oxide (SiO₂) film without generating voids and seams.

Thus, in a proposed method for manufacturing semiconductor devices from the 100-nm generation onward, coating-type solution SOG (spin-on-glass) is used to fill the STI groove with device isolation insulating film. In particular, among SOG-based chemicals, a silazane perhydride polymer solution having relatively small volume shrinkage recently draws attention. 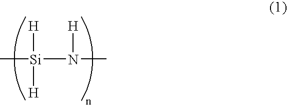
As shown in Formula (1), silazane perhydride has a structure of —(SiH₂—NH)ₙ—. Hence it reacts with water (H₂O) in the atmosphere to generate ammonia (NH₃). On the other hand, the closed-type transport container is made of polycarbonate (PC) or polybutylene terephthalate (PBT), and hence the material of the closed-type transport container reacts with NH₃. That is, as described below, when a semiconductor wafer with exposed polysilazane (PSZ) film formed by baking silazane perhydride coating is stored in the closed-type transport container, NH₃ generated from the PSZ film reacts with the material of the closed-type transport container and causes cross-contamination.

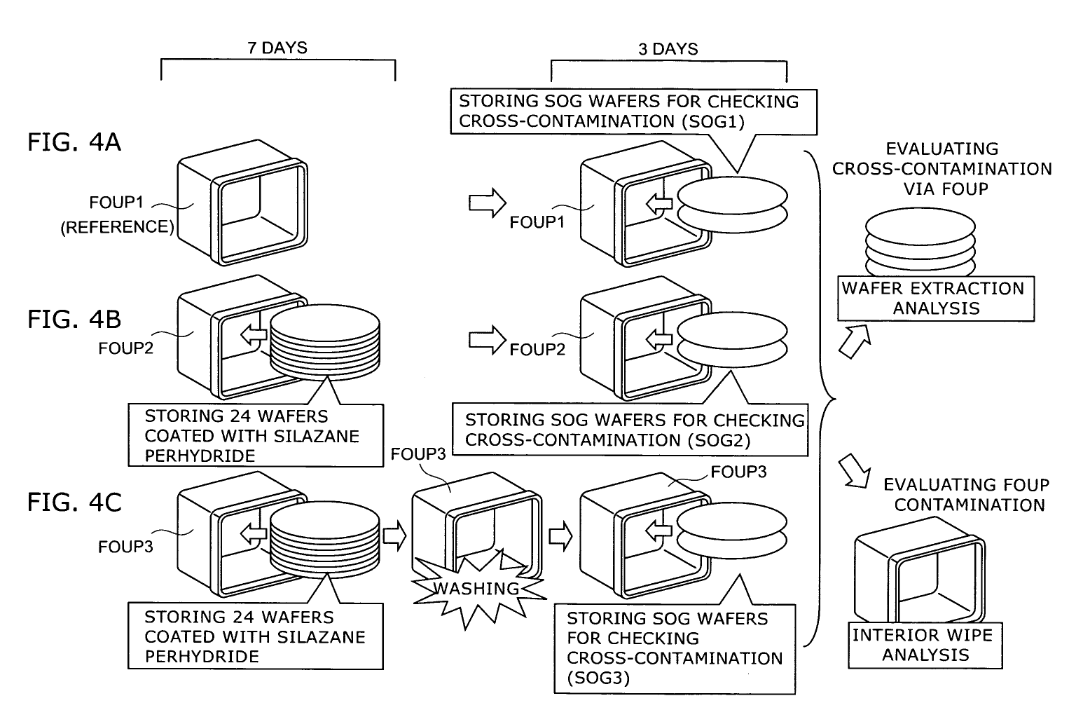

Three closed-type transport containers, that is, a closed-type transport container (FOUP) 1 shown in FIG. 4A, a closed-type transport container (FOUP) 2 shown in FIG. 4B, and a closed-type transport container (FOUP) 3 shown in FIG. 4C, were prepared, and contamination of the closed-type transport containers by PSZ film was examined in the following procedure, where the closed-type transport container (FOUP) 1 shown in FIG. 4A is a closed-type transport container for producing a reference sample:

(a) First, for preparing “intermediate products”, 48 semiconductor wafers (Si wafers) measuring 300 mm in diameter were each coated with a silazane perhydride polymer solution to a thickness of 600 nm by spin coating. Then the silazane perhydride coating was baked at 150° C. for three minutes. Thus PSZ film was formed on each of the 48 semiconductor wafers.

(b) As shown in FIG. 4A, the closed-type transport container (FOUP) 1 for producing a reference sample was left empty and retained in the clean room for seven days. On the other hand, the 48 semiconductor wafers with PSZ film formed thereon as described above were divided into two sets of 24 semiconductor wafers, and each set was stored for seven days in the closed-type transport containers (FOUP) 2 and 3 as shown in FIGS. 4B and 4C, respectively, so that the wafers are inserted into grooves (slots) 1 to 24.

(c) Then, as shown in FIG. 4A, in the closed-type transport container (FOUP) 1 for producing a reference sample, two wafers (SOG1) with SOG film other than PSZ film (hereinafter referred to as “non-silazane SOG film”) for checking cross-contamination was inserted into grooves (slots) 1 and 24 and retained for three days. On the other hand, as shown in FIG. 4B, the 24 semiconductor wafers with PSZ film formed thereon were retrieved from the closed-type transport container (FOUP) 2, which was directly used to store two wafers (SOG2) with non-silazane SOG film for checking cross-contamination in grooves 1 and 24 for three days. In contrast, as shown in FIG. 4C, the 24 semiconductor wafers with PSZ film formed thereon were retrieved from the closed-type transport container (FOUP) 3, which was then washed in the automatic container washer. After the washing, as shown in FIG. 4C, in the closed-type transport container (FOUP) 3, two wafers (SOG3) with non-silazane SOG film for checking cross-contamination were inserted into grooves 1 and 24 and retained for three days.

(d) Then the inner wall of each closed-type transport container (FOUP) 1, 2, 3 was wiped with waste soaked with pure water, the waste was subjected to pure water extraction, and the amount of NH₃ attached to the closed-type transport container was determined by ion chromatography. Furthermore, NH₃ adsorbed on the non-silazane SOG film 1, 2, 3 for checking cross-contamination was also determined by pure water extraction and ion chromatography.

The result of the above procedure (a) to (d) for examining the contamination of the closed-type transport containers caused by silazane perhydride is listed on TABLE 1.

TABLE 1

| | Amount of NH₃ adsorbed | Amount of NH₃ adsorbed |
|---|---|---|
| | on container inner wall | on non-silazane SOG film |
| FOUP1 | 0.24 (μg) | 0.63 (μg) |
| FOUP2 | 0.94 (μg) | 8.3 (μg) |
| FOUP3 | 0.19 (μg) | 6.6 (μg) |

It can be seen in TABLE 1 that the amount of NH₃ adsorbed on the inner wall of the closed-type transport container (FOUP) 2 having stored wafers with PSZ film is about four times larger than that on the inner wall of the reference closed-type transport container (FOUP) 1. On the other hand, the amount of NH₃ adsorbed on the inner wall of the closed-type transport container (FOUP) 3 having stored wafers with PSZ film is smaller than that on the inner wall of the reference closed-type transport container (FOUP) 1. Hence it turns out that the adsorbed NH₃ is eliminated by washing the closed-type transport container.

However, as seen in the result of cross-contamination due to adsorption on the non-silazane SOG film formed on the surface of the semiconductor wafer shown in the right column of TABLE 1, NH₃ contamination was detected not only from the SOG wafer (SOG2) stored in the closed-type transport container (FOUP) 2 with NH₃ adsorbed on the inner wall, but also from the SOG wafer (SOG3) stored in the washed closed-type transport container (FOUP) 3. This indicates that, even if NH₃ adsorbed on the inner wall surface of the closed-type transport container was washed away, NH₃ remains trapped in the material of the closed-type transport container and is gradually released into the closed-type transport container. This is adsorbed on the non-silazane SOG film formed on the surface of the stored semiconductor wafer to cause cross-contamination.

Cross-Contamination Via a Closed-Type Transport Container Due to PSZ Film: Case 2

Next, a description is given of NH₃ cross-contamination from the polysilazane (PSZ) film which is formed by baking silazane perhydride coating at 150° C. for three minutes and is further oxidized in water vapor-containing atmosphere at a temperature higher than 200° C. and not higher than 600° C. When the temperature of oxidation of the PSZ film is lower than 400° C., silazane structures such as Si—H, N—H, and Si—N remain in the PSZ film. That is, the PSZ film is not a perfect SiO₂ film. Thus:

(a) First, for preparing “intermediate products”, 24 semiconductor wafers (Si wafers) measuring 300 mm in diameter were each coated with a silazane perhydride polymer solution to a thickness of 600 nm by spin coating, which was baked at 150° C. for three minutes to form PSZ film. The PSZ film was further oxidized in water vapor at a temperature lower than 400° C., e.g. 300° C. (the resulting PSZ film being hereinafter referred to as “oxidized PSZ film”). Thus 24 semiconductor wafers with the oxidized PSZ film on the surface thereof were prepared.

(b) The 24 semiconductor wafers with the oxidized PSZ film formed thereon were inserted into grooves (slots) 1 to 24, respectively, of a closed-type transport container (FOUP) 4 and retained for three days.

(c) After three days, the 24 semiconductor wafers with the oxidized PSZ film formed thereon were retrieved from the closed-type transport container (FOUP) 4. Then, in the closed-type transport container (FOUP) 4, two wafers (SOG4) with non-silazane SOG film for checking cross-contamination were inserted into grooves 1 and 24 and retained for three days.

(d) Then the two wafers (SOG4) with non-silazane SOG film were retrieved from the closed-type transport container (FOUP), and NH₃ adsorbed on the non-silazane SOG film 4 for checking cross-contamination was determined by pure water extraction and ion chromatography.

According to the ion chromatography, NH₃ cross-contamination of 9.5 μg was detected also from the oxidized PSZ film which was oxidized at 300° C. It can be seen by comparison with the result of TABLE 1 that cross-contamination from the PSZ film oxidized at a temperature of 300° C., which is higher than in the case of TABLE 1, is also serious.

Influence of Cross-Contamination on Manufacturing Processes

As described above, NH₃ contamination in a closed-type transport container causes cross-contamination where semiconductor wafers subsequently stored as “intermediate products” in the closed-type transport container are contaminated.

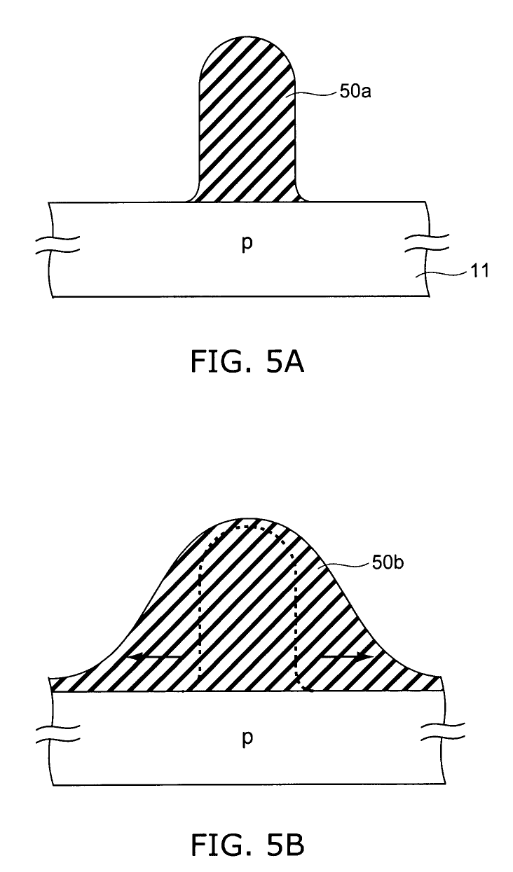

Some kinds of photoresist film react with NH₃. Such photoresist film causes adhesion failure and patterning distortion. In particular, if the photoresist film is processed into a thin line-and-space pattern followed by reacting with NH₃ contamination, a shape called “skirt” as shown in FIG. 5B occurs. This is a defective shape as compared with photoresist film in the non-contaminated (normal) condition as shown in FIG. 5A.

Robot-Transport Manufacturing Method Discriminating Between Closed-Type Transport Containers

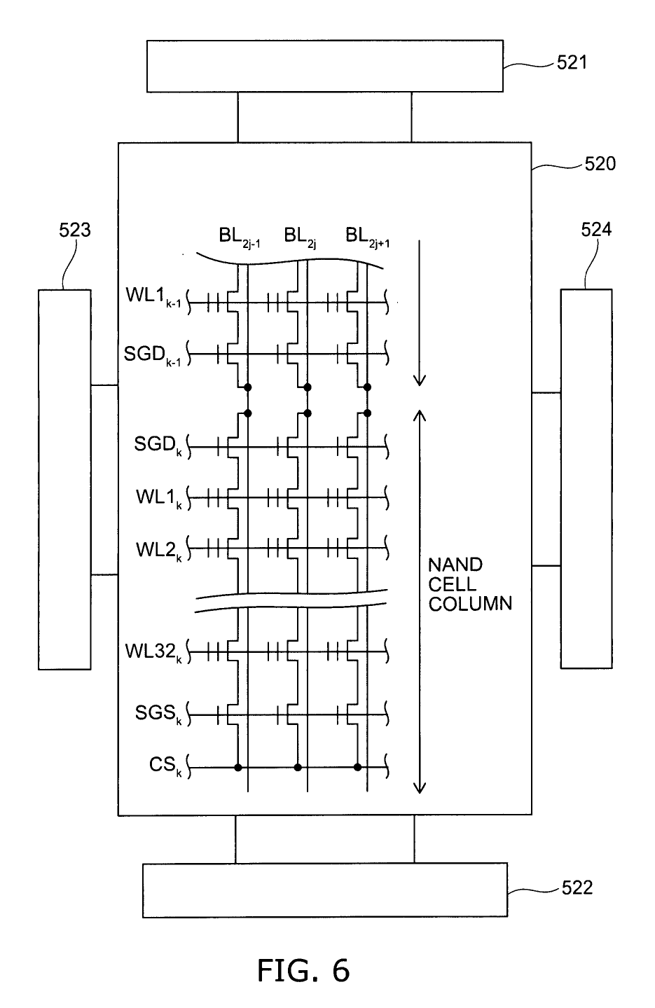

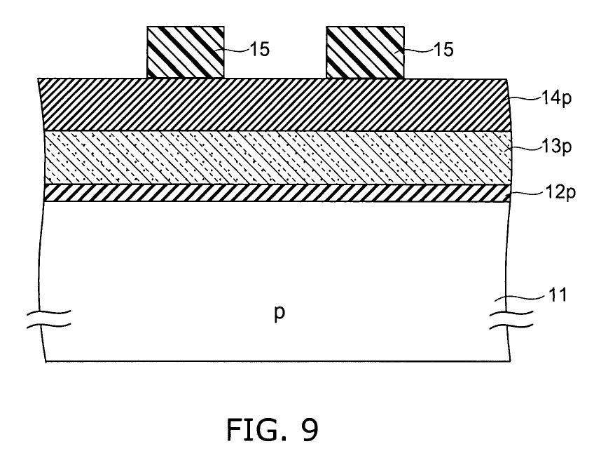

With reference to FIGS. 9 to 22, a method for manufacturing a NAND nonvolatile semiconductor memory device will be described, where interprocess transport paths for transporting semiconductor wafers with exposed PSZ film are defined as “specific interprocess transport paths”, and a silazane perhydride polymer solution is used as an STI filling material. However, by way of introduction, a completed NAND nonvolatile semiconductor memory device is described with reference to FIGS. 6 to 8.

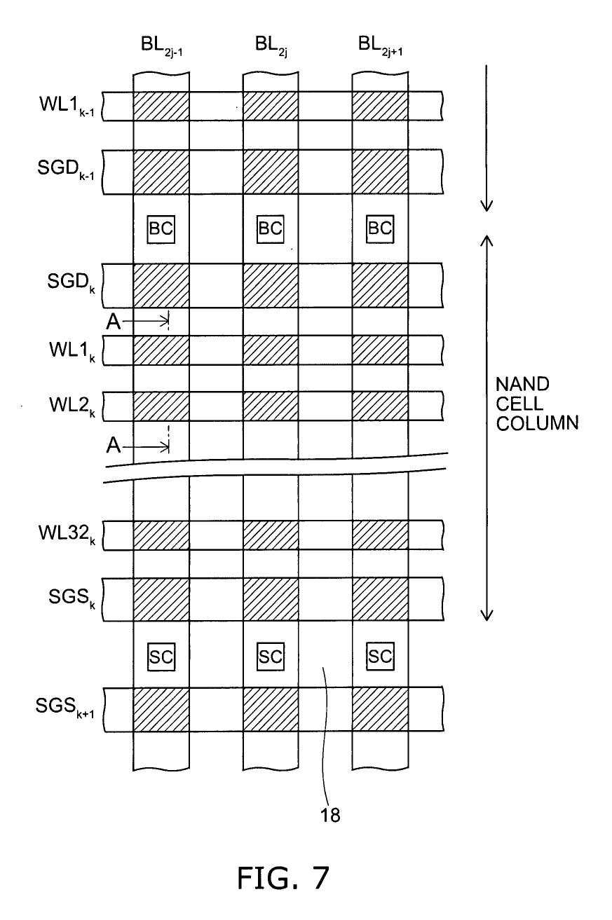

FIG. 6 is a block diagram schematically showing a logical circuit configuration of a NAND nonvolatile semiconductor memory device (flash memory). A memory cell array 520 is surrounded by peripheral circuits (21, 22, 23, 24) such as a top page buffer 521, a bottom page buffer 522, a left row decoder/charge pump 523, and a right row decoder/charge pump 524. As shown in FIG. 7, the memory cell array 520 comprises a plurality of word lines WL1ₖ, WL2ₖ, . . . , WL32ₖ, WL1ₖ₋₁, . . . arranged in the row direction and a plurality of bit lines BL₂ⱼ₋₁, BL₂ⱼ, BL₂ⱼ₊₁, . . . arranged in the column direction orthogonal to the word lines WL1ₖ, WL2ₖ, . . . , WL32ₖ, WL1ₖ₋₁, . . . . In the column direction of FIG. 7, memory cell transistors each having a charge storage layer are arranged, where the charge storage state of the charge storage layer is controlled by one of the plurality of word lines WL1ₖ, WL2ₖ, . . . , WL32ₖ, WL1ₖ₋₁, . . . . As shown in the plan view of FIG. 7, device isolation insulating films 18 made of PSZ film run parallel to the column direction, and thereby the memory cell transistors adjacent to each other across the device isolation insulating film 18 made of PSZ film are isolated from each other. FIGS. 6 and 7 show a configuration where 32 memory cell transistors are arranged in the column direction to form a memory cell column. At both ends of the arrangement of these memory cell columns, pairs of select transistors for selecting a set of memory cell transistors arranged in the memory cell column are placed adjacent to each other in the column direction. A pair of select gate interconnects SGDₖ, SGSₖ are connected to the gates of the pair of select transistors, respectively. The top page buffer 521 and the bottom page buffer 522 are connected to the bit lines BL₂ⱼ₋₁, BL₂ⱼ, BL₂ⱼ₊₁, . . . and each serve as a buffer in reading the associated memory cell column information. The left row decoder/charge pump 523 and the right row decoder/charge pump 524 are connected to the word lines WL1ₖ, WL2ₖ, WL32ₖ, WL1ₖ₋₁, . . . to control the charge storage state of each memory cell transistor constituting the memory cell column.

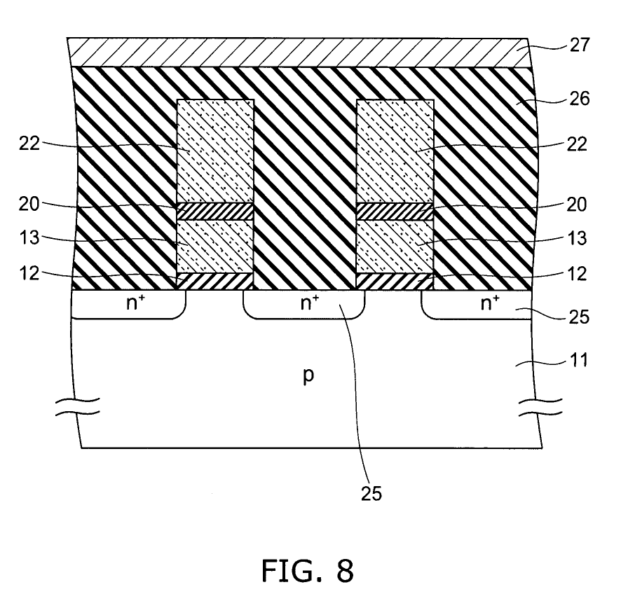

FIG. 8 is a schematic cross-sectional view showing part of the memory cell array 520 as viewed along the A-A direction (column direction) in FIG. 7. That is, FIG. 8 corresponds to a cross section taken along the direction of the bit lines BL₂ⱼ₋₁, BL₂ⱼ, BL₂ⱼ₊₁, . . . in FIG. 6. As shown in the cross-sectional view of FIG. 8, a source/drain region 25 of the memory cell transistor is formed in the surface of a p-type semiconductor substrate 11, and a gate insulating film (tunnel oxide film) 12 is located on a channel region defined between each pair of source/drain regions 25. The source/drain region 25 is an n⁺-type semiconductor region formed by doping the p-type semiconductor substrate 11 with n-type dopants at high concentration. Although not shown in FIG. 8, but obviously from FIGS. 6 and 7, a select transistor having nearly the same structure as the memory cell transistor is located at the end of the memory cell column, and the source/drain region of the select transistor serves as a bit line contact region. The p-type semiconductor substrate 11 may be replaced by a p-type well region (p-well) formed in an n-type semiconductor substrate.

A floating electrode 13 for storing charge, an interelectrode insulating film 20 on the floating electrode 13, and a control electrode 22 on the interelectrode insulating film 20 are located on the gate insulating film (tunnel oxide film) 12 to constitute a gate electrode of each memory cell transistor. Although not shown, the select transistor also has a gate electrode structure comprising a gate insulating film (tunnel oxide film) 12, a floating electrode 13, an interelectrode insulating film 20, and a control electrode 22 electrically continuous with the floating electrode 13 through an opening in the interelectrode insulating film 20. However, the control electrode 22 is electrically continuous with the floating electrode 13 through an interelectrode insulating film short-circuit window of the interelectrode insulating film 20. As can be understood from FIG. 7, the floating electrodes 13 of the memory cell transistors belonging to adjacent memory cell columns are opposed to each other in the row direction (word line direction) across the device isolation insulating film 18 made of PSZ film constituting the STI.

The floating electrode 13 serving as a charge storage layer is formed from polycrystalline silicon film doped with n-type dopants such as phosphorus (P) or arsenic (As) (hereinafter referred to as “doped polycrystalline silicon film”).

The control electrode 22 may have a three-layer structure composed of a polycrystalline silicon film doped with n-type dopants, a tungsten silicide (WSi₂) film, and a cap insulating film. The tungsten silicide (WSi₂) film may be replaced by any other metal silicide film such as cobalt silicide (CoSi₂) film, titanium silicide (TiSi₂) film, or molybdenum silicide (MoSi₂) film. Instead of silicide film, high-melting-point metal such as tungsten (W), cobalt (Co), titanium (Ti), or molybdenum (Mo), or polycide film based on these silicide films may be used. Instead of using silicide film, a highly conductive metal film made of aluminum (Al) or copper (Cu) may be placed on the polycrystalline silicon film to also serve as the word lines WL1ₖ, WL2ₖ, . . . , WL32ₖ, WL1ₖ₋₁, . . . . Alternatively, the silicide film may be replaced by a laminated film made of one or more of tungsten nitride (WN) film and titanium nitride (TiN, TiN₂) film on the polycrystalline silicon film.

Although not shown, the peripheral transistor is configured as a transistor having nearly the same laminated structure as the select transistor, or as a transistor having a gate electrode corresponding to the structure only with the control electrode 22 where the floating electrode 13 and the interelectrode insulating film 20 are removed from the laminated structure of the select transistor.

As is obvious from the cross-sectional view taken along the bit line direction shown in FIG. 8, in the semiconductor memory device according to the embodiment of the invention, the floating electrodes 13 of the memory cell transistors are opposed to each other across an interlayer insulating film 26. Here, when an interlayer insulating film 26 having a relative dielectric constant εᵣ lower than 3.9 is buried between each pair of floating electrodes 13 of the plurality of memory cell transistors arranged in the column direction, miswrite due to the interference effect between cells neighboring in the column direction can be prevented from occurring between memory cell transistors adjacent to each other in the same column.

In FIG. 8, the detailed structure is not shown. However, for example, a cell isolation underlying film made of silicon oxide film having a thickness of about 6 nm may be formed on the sidewall of the laminated structure (13, 20, 22) composed of the polycrystalline silicon film (first conductive layer) 13, the interelectrode insulating film 20, and the control electrode 22. A two-layer structure composed of an interlayer insulating film 26 and a core filling insulating film may be used between the select transistors of cell columns adjacent to each other in the row direction. The core filling insulating film can be made of BPSG film, for example. That is, the center of a recess formed by the interlayer insulating film 26 may be filled with a core filling insulating film, and a contact plug may be buried to pass through the center of the core filling insulating film. The contact plug has a low contact resistance and forms ohmic contact with the bit line contact region (not shown). The contact plug is connected to the bit line (BL₂ⱼ) 27 located on the interlayer insulating film 26. In FIG. 8, the bit line 27 is located on the interlayer insulating film 26. However, damascene interconnect may also be used, where a damascene trench is formed in the interlayer insulating film 26, and metal interconnect primarily composed of copper (Cu) is buried inside the damascene trench.

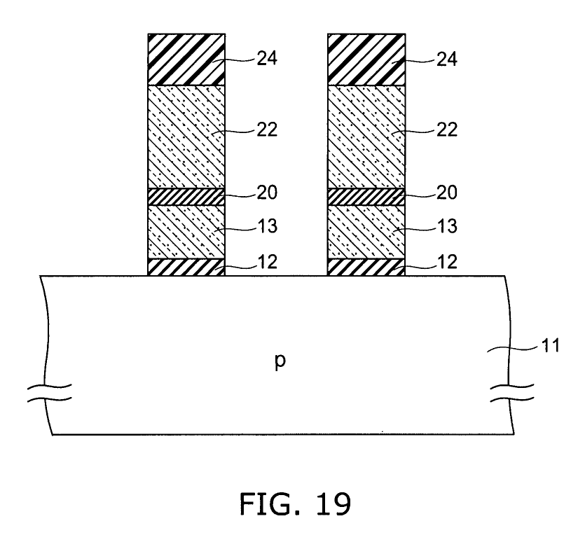

Having made preliminary remarks, a robot-transport manufacturing method according to the embodiment of the invention is now described with reference to FIGS. 9 to 22. Here, FIGS. 9 to 18 are cross-sectional views taken parallel to the word lines WL1ₖ, WL2ₖ, . . . , WL32ₖ, WL1ₖ₋₁, . . . shown in FIG. 7 and cutting a particular word line. FIGS. 19 to 22 are cross-sectional views taken parallel to the bit lines BL₂ⱼ₋₁, BL₂ⱼ, BL₂ⱼ₊₁, . . . corresponding to the A-A direction in FIG. 7.

The flow of manufacturing processes shown in FIGS. 9 to 22 is presented for convenience of describing a robot-transport manufacturing method according to the embodiment of the invention. In practice, some other processes such as an ion implantation process for threshold control may be added to the flow of the method for manufacturing a NAND nonvolatile semiconductor memory device (flash memory) shown in the following (a) to (w). That is, the method for manufacturing a NAND nonvolatile semiconductor memory device described below is an example for understanding of the content of the robot-transport manufacturing method. It is understood that NAND nonvolatile semiconductor memory devices can be manufactured by various other flows of manufacturing processes, including the above variation, within the spirit and scope of the invention.

(a) For simplicity of description, it is assumed that, under the command from the apparatus group control server 51 shown in FIG. 1, a closed-type transport container of transport type 1 is already selected and that a p-type silicon substrate 11 (or n-type silicon substrate with p-type wells formed therein) is stored as an “intermediate product” in the closed-type transport container of transport type 1. The closed-type transport container of transport type 1 (hereinafter referred to as “type 1 container”) storing the silicon substrate 11 (or n-type silicon substrate with p-type wells formed therein) is transported to the container passing mechanism for loading (loader) 55ᵢ of the washer 58ᵢ via the transport rail 54. On the basis of the container information communicated from the apparatus group control server 51 shown in FIG. 1, the RF tag receiver (container identification information input means) 59 installed on the transfer chamber 57ᵢ reads a signal (container identification information) from the RF tag (container identification information output means) 64 provided on the type 1 container and determines whether the type 1 container transported to the loader 55ᵢ has a correct transport type. If it is determined that the transport type is correct, the lid of the type 1 container is automatically opened in the loader 55ᵢ, and the semiconductor wafer (silicon substrate) 11 is transferred from the type 1 container to the washer 58ᵢ through the local clean transfer chamber 57ᵢ (in the following (b) to (w), the description of the processing for determining the transport type of the closed-type transport container in the corresponding loaders 55ᵢ, 55ᵢ₊₁, 55ᵢ₊₂, 55ᵢ₊₃, . . . will be omitted). Upon the transfer of the semiconductor wafer (silicon substrate) 11, the washer 58ᵢ starts washing the semiconductor wafer (silicon substrate) 11. The semiconductor wafer 11 washed in accordance with the recipe transmitted from the apparatus group control server 51 is transferred to the container passing mechanism for unloading (unloader) 56ᵢ through the transfer chamber 57ᵢ. Inside the unloader 56ᵢ, the semiconductor wafer 11 is automatically stored in the type 1 container. The lid of the type 1 container is automatically closed. Then the type 1 container is robot-transported via the transport rail 54 to the loader 55ᵢ₊₁ of the gate oxidation apparatus 58ᵢ₊₁.

(b) The lid of the type 1 container is automatically opened in the loader 55ᵢ₊₁ of the gate oxidation apparatus 58ᵢ₊₁, and the semiconductor wafer 11 is transferred from the type 1 container to the gate oxidation apparatus 58ᵢ₊₁ through the local clean transfer chamber 57ᵢ₊₁. In accordance with the recipe transmitted from the apparatus group control server 51, a tunnel oxide film 12p is formed on the semiconductor wafer 11. The tunnel oxide film 12p is formed to a thickness of about 1 to 15 nm, e.g. about 8 nm. Then the semiconductor wafer 11 is transferred to the unloader 56ᵢ₊₁ through the transfer chamber 57ᵢ₊₁. Inside the unloader 56ᵢ₊₁, the semiconductor wafer 11 is automatically stored in the type 1 container. The lid of the type 1 container is automatically closed. Then the type 1 container is robot-transported via the transport rail 54 to the loader 55ᵢ₊₂ of the polysilicon reduced-pressure CVD apparatus 58ᵢ₊₂.

(c) The lid of the type 1 container is automatically opened in the loader 55ᵢ₊₂ of the polysilicon reduced-pressure CVD apparatus 58ᵢ₊₂, and the semiconductor wafer 11 is transferred from the type 1 container to the polysilicon reduced-pressure CVD apparatus 58ᵢ₊₂ through the transfer chamber 57ᵢ₊₂. In accordance with the recipe transmitted from the apparatus group control server 51, a polycrystalline silicon film (first conductive layer) 13p serving as a floating electrode 13 is deposited on the tunnel oxide film 12p. The first conductive layer (polycrystalline silicon film) 13p is deposited to a thickness of about 10 to 200 nm, e.g. about 150 nm. Then the semiconductor wafer 11 is transferred to the unloader 56ᵢ₊₂ through the transfer chamber 57ᵢ₊₂. Inside the unloader 56ᵢ₊₂, the semiconductor wafer 11 is automatically stored in the type 1 container. The lid of the type 1 container is automatically closed. Then the type 1 container is robot-transported via the transport rail 54 to the loader 55ᵢ₊₃ of the nitride film reduced-pressure CVD apparatus 58ᵢ₊₃.

(d) The lid of the type 1 container is opened in the loader 55ᵢ₊₃ of the nitride film reduced-pressure CVD apparatus 58ᵢ₊₃, and the semiconductor wafer 11 is transferred from the type 1 container to the nitride film reduced-pressure CVD apparatus 58ᵢ₊₃ through the transfer chamber 57ᵢ₊₃. In accordance with the recipe transmitted from the apparatus group control server 51, an Si₃N₄ film serving as a CMP stopper layer 14p is deposited on the first conductive layer (polycrystalline silicon film) 13p. The CMP stopper layer (Si₃N₄ film) 14p is deposited to a thickness of about 80 to 300 nm, e.g. about 100 nm. Then the semiconductor wafer 11 is transferred to the unloader 56ᵢ₊₃ through the transfer chamber 57ᵢ₊₃. Inside the unloader 56ᵢ₊₃, the semiconductor wafer 11 is stored in the type 1 container. The lid of the type 1 container is closed. Then the type 1 container is robot-transported via the transport rail 54 to the loader 55ᵢ₊₄ of the spinner 58ᵢ₊₄.

(e) The lid of the type 1 container is opened in the loader 55ᵢ₊₄ of the spinner 58ᵢ₊₄, and the semiconductor wafer 11 is transferred from the type 1 container to the rotary stage of the spinner 58ᵢ₊₄ through the transfer chamber 57ᵢ₊₄. In accordance with the recipe transmitted from the apparatus group control server 51, a photoresist film 15 is applied onto the entire surface of the CMP stopper layer 14p. The semiconductor wafer 11 coated with the photoresist film 15, after prebaking, is transferred to the unloader 56ᵢ₊₄ through the transfer chamber 57ᵢ₊₄. Inside the unloader 56ᵢ₊₄, the semiconductor wafer 11 is stored in the type 1 container. The lid of the type 1 container is closed. Then the type 1 container is robot-transported via the transport rail 54 to the loader 55ᵢ₊₅ of the stepper 58ᵢ₊₅.

(f) The lid of the type 1 container is opened in the loader 55ᵢ₊₅ of the stepper 58ᵢ₊₅, and the semiconductor wafer 11 is transferred from the type 1 container to the exposure stage of the stepper 58ᵢ₊₅ through the transfer chamber 57ᵢ₊₅. In accordance with the recipe transmitted from the apparatus group control server 51, an image of a prescribed mask pattern is projected on the photoresist film 15 by the step-and-repeat exposure, and thereby the image of a desired mask pattern is transferred. The semiconductor wafer 11 with the image of the mask pattern transferred thereon, after postbaking, is transferred to the unloader 56ᵢ₊₅ through the transfer chamber 57ᵢ₊₅. Inside the unloader 56ᵢ₊₅, the semiconductor wafer 11 is stored in the type 1 container. The lid of the type 1 container is closed. Then the type 1 container is robot-transported via the transport rail 54 to the loader 55ᵢ₊₆ of the developing apparatus 58ᵢ₊₆.

(g) The lid of the type 1 container is opened in the loader 55ᵢ₊₆ of the developing apparatus 58ᵢ₊₆, and the semiconductor wafer 11 is transferred from the type 1 container to the developing apparatus 58ᵢ₊₆ through the transfer chamber 57ᵢ₊₆. In accordance with the recipe transmitted from the apparatus group control server 51, the photoresist film 15 is developed by developer liquid. As a result, as shown in FIG. 9, a resist mask 15 is formed on the CMP stopper layer 14p. The semiconductor wafer 11 with the resist mask 15 formed thereon, after resist curing, is transferred to the unloader 56ᵢ₊₆ through the transfer chamber 57ᵢ₊₆. Inside the unloader 56ᵢ₊₆, the semiconductor wafer 11 is stored in the type 1 container. The lid of the type 1 container is closed. Then the type 1 container is robot-transported via the transport rail 54 to the loader 55ᵢ₊₇ of the RIE apparatus 58ᵢ₊₇.

(h) The lid of the type 1 container is opened in the loader 55ᵢ₊₇ of the RIE apparatus 58ᵢ₊₇, and the semiconductor wafer 11 is transferred from the type 1 container into the etching chamber of the RIE apparatus 58ᵢ₊₇ through the transfer chamber 57ᵢ₊₇. In accordance with the recipe transmitted from the apparatus group control server 51, the resist mask 15 is used to continuously etch the CMP stopper layer 14p, the first conductive layer 13p, and the tunnel oxide film 12p, thereby forming a sequentially laminated pattern of a tunnel oxide film 12, a first conductive layer 13, a silicon nitride film 14, and the resist mask 15. Continuous RIE is further carried on in the etching chamber of the RIE apparatus 58ᵢ₊₇ to etch the silicon substrate 11. After completion of the continuous RIE, the semiconductor wafer 11 is transferred to the unloader 56ᵢ₊₇ through the transfer chamber 57ᵢ₊₇. Inside the unloader 56ᵢ₊₇, the semiconductor wafer 11 is stored in the type 1 container. The lid of the type 1 container is closed. Then the type 1 container is robot-transported via the transport rail 54 to the loader 55ᵢ of the washer 58ᵢ.

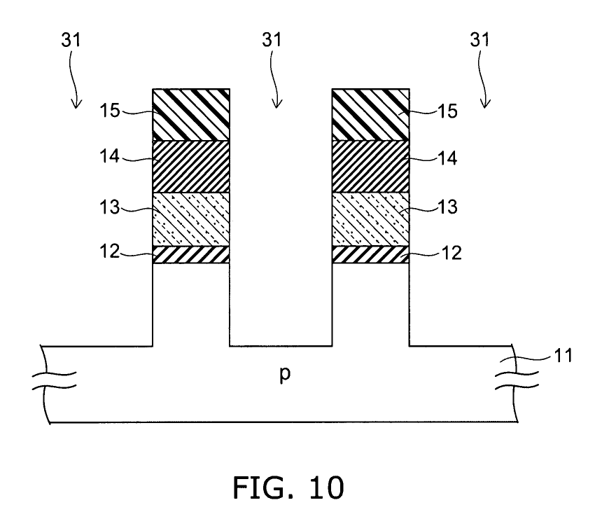

(i) The lid of the type 1 container is opened in the loader 55ᵢ of the washer 58ᵢ, and the semiconductor wafer 11 is transferred from the type 1 container to the washer 58ᵢ through the transfer chamber 57ᵢ. In accordance with the recipe transmitted from the apparatus group control server 51, the resist mask 15 is removed. Upon removal of the resist mask 15, as shown in FIG. 10, device isolation grooves 31 are formed in the silicon substrate 11. In FIG. 10, the device isolation grooves 31 are formed as stripes extending perpendicular to the page and parallel to each other. The protrusion made of the semiconductor substrate 11 sandwiched on both sides between the device isolation grooves 31 serves as an active region (AA). During the process of removing the resist mask 15, the apparatus group control server 51 shown in FIG. 1 uses the product information to derive the next process, which is a process of applying a silazane perhydride polymer solution 18p, and to determine that the interprocess transport path to the silazane perhydride coater 58ᵢ₊₈ is to be a “specific interprocess transport path”. The apparatus group control server 51 generates container information for the “specific interprocess transport path” and communicates it to the washer 58ᵢ to instruct the type change of the closed-type transport container 60. As a result, the empty type 1 container is transported from the loader 55ᵢ of the washer 58ᵢ via the transport rail 54 to the container discrimination/selection apparatus 53a, 53b shown in FIG. 1. The container discrimination/selection apparatus 53a, 53b uses the signal (container identification information) from the RF tag 64 to select, in the temporary container cabinet 52a, 52b shown in FIG. 1, a closed-type transport container of transport type 2 (hereinafter referred to as “type 2 container”). That is, under the command from the apparatus group control server 51, the container discrimination/selection apparatus 53a, 53b selects a type 2 container and moves the selected type 2 container to the unloader 56ᵢ of the washer 58ᵢ via the transport rail 54. The semiconductor wafer 11 from which the resist mask 15 has been removed is transferred to the unloader 56ᵢ through the transfer chamber 57ᵢ. Inside the unloader 56ᵢ, the semiconductor wafer 11 is stored in the type 2 container. The lid of the type 2 container is closed. Then the type 2 container is robot-transported via the transport rail 54 to the loader 55ᵢ₊₈ of the silazane perhydride coater 58ᵢ₊₈.

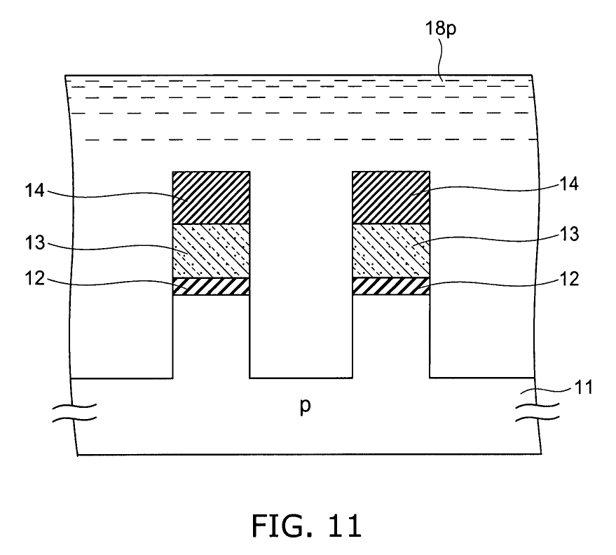

(j) The lid of the type 2 container is opened in the loader 55ᵢ₊₈ of the silazane perhydride coater 58ᵢ₊₈, and the semiconductor wafer 11 is transferred from the type 2 container to the rotary stage of the silazane perhydride coater 58ᵢ₊₈ through the transfer chamber 57ᵢ₊₈. In accordance with the recipe transmitted from the apparatus group control server 51, a silazane perhydride polymer solution 18p is applied, by spin coating, onto the entire surface of the silicon substrate 11, the tunnel oxide film 12p, the floating electrode 13, and the Si₃N₄ film 14 so as to completely fill the device isolation grooves 31 as shown in FIG. 11. The silazane perhydride polymer solution 18p is applied to a thickness of about 500 to 1000 nm, e.g. about 600 nm. Then the semiconductor wafer 11 is transferred to the unloader 56ᵢ₊₈ through the transfer chamber 57ᵢ₊₈. Inside the unloader 56ᵢ₊₈, the semiconductor wafer 11 is stored in the type 2 container. The lid of the type 2 container is closed. Then the type 2 container is robot-transported via the transport rail 54 to the loader 55ᵢ₊₉ of the silazane perhydride baking apparatus 58ᵢ₊₉.

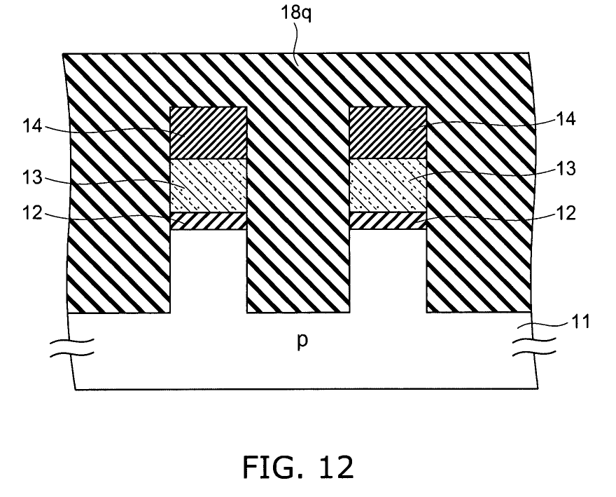

(k) The lid of the type 2 container is opened in the loader 55ᵢ₊₉ of the silazane perhydride baking apparatus 58ᵢ₊₉, and the semiconductor wafer 11 is transferred from the type 2 container to the silazane perhydride baking apparatus 58ᵢ₊₉ through the transfer chamber 57ᵢ₊₉. In accordance with the recipe transmitted from the apparatus group control server 51, the silazane perhydride polymer solution (silazane perhydride coating) 18p applied by the silazane perhydride coater 58ᵢ₊₈ is baked at 200° C. or less, e.g. about 150° C., for about three minutes. By this baking process, the solvent of the silazane perhydride polymer solution 18p is volatilized to form a polysilazane (PSZ) film 18q as shown in FIG. 12. The semiconductor wafer 11 with the PSZ film 18q formed thereon is transferred to the unloader 56ᵢ₊₉ through the transfer chamber 57ᵢ₊₉. Inside the unloader 56ᵢ₊₉, the semiconductor wafer 11 is stored in the type 2 container. The lid of the type 2 container is closed. Then the type 2 container is robot-transported via the transport rail 54 to the loader 55ᵢ₊₁₀ of the PSZ film oxidation apparatus 58ᵢ₊₁₀.

(l) The lid of the type 2 container is opened in the loader 55ᵢ₊₁₀ of the PSZ film oxidation apparatus 58ᵢ₊₁₀, and the semiconductor wafer 11 is transferred from the type 2 container to the PSZ film oxidation apparatus 58ᵢ₊₁₀ through the transfer chamber 57ᵢ₊₁₀. In accordance with the recipe transmitted from the apparatus group control server 51, the PSZ film 18q formed by the silazane perhydride baking apparatus 58ᵢ₊₉ is oxidized at a temperature higher than 200° C. and not higher than 600° C. By this oxidation, the PSZ film 18q is transformed to an SiO₂ film 18r. The semiconductor wafer 11 with the PSZ film 18q transformed to the SiO₂ film 18r is transferred to the unloader 56ᵢ₊₁₀ through the transfer chamber 57ᵢ₊₁₀. Inside the unloader 56ᵢ₊₁₀, the semiconductor wafer 11 is stored in the type 2 container. The lid of the type 2 container is closed. Then the type 2 container is robot-transported via the transport rail 54 to the loader 55ᵢ₊₁₁ of the CMP apparatus 58ᵢ₊₁₁.

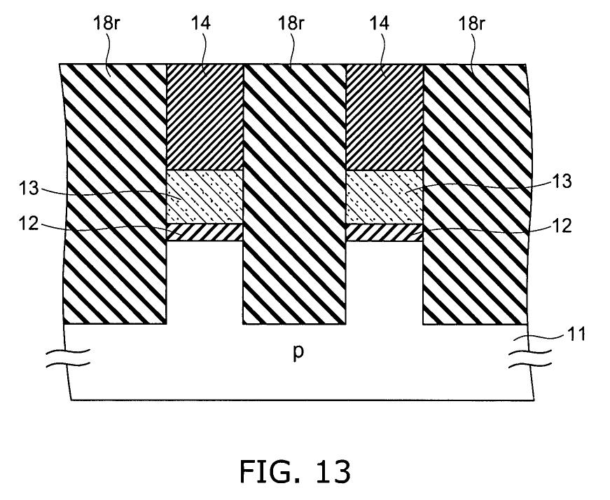

(m) The lid of the type 2 container is opened in the loader 55ᵢ₊₁₁ of the CMP apparatus 58ᵢ₊₁₁, and the semiconductor wafer 11 is transferred from the type 2 container to the CMP apparatus 58ᵢ₊₁₁ through the transfer chamber 57ᵢ₊₁₁. In accordance with the recipe transmitted from the apparatus group control server 51, the Si₃N₄ film is used as a CMP stopper layer 14 to polish the SiO₂ film 18r outside the trench and to planarize the surface by the CMP process as shown in FIG. 13. The semiconductor wafer 11 with the surface planarized is transferred to the unloader 56ᵢ₊₁₁ through the transfer chamber 57ᵢ₊₁₁. Inside the unloader 56ᵢ₊₁₁, the semiconductor wafer 11 is stored in the type 2 container. The lid of the type 2 container is closed. Then the type 2 container is robot-transported via the transport rail 54 and the interbay container transport rail 50 to the loader 55_{i+q} (not shown) of a wet etching apparatus 58_{i+q} in the adjacent bay area, not shown.

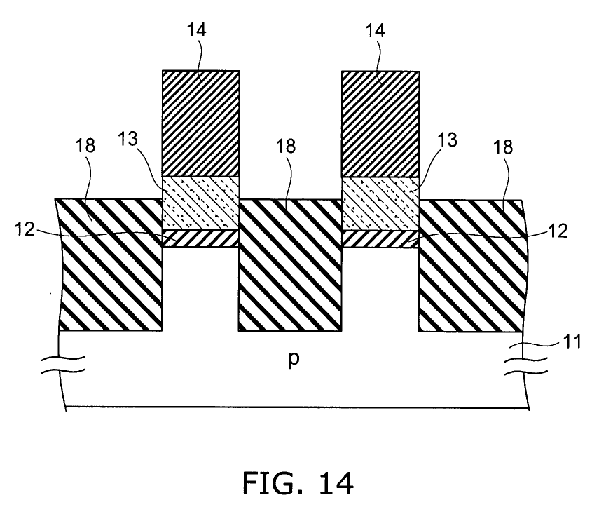

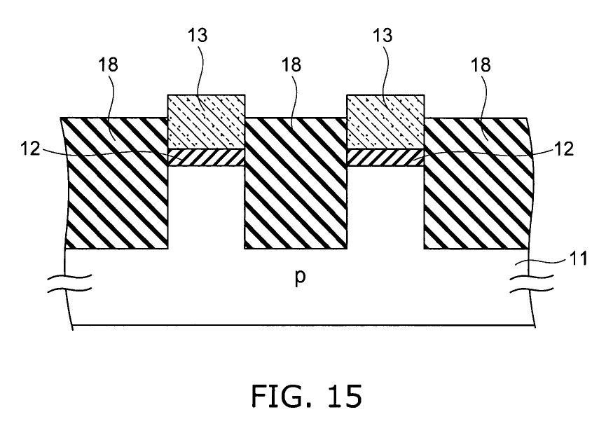

(n) The lid of the type 2 container is opened in the loader 55_{i+q} of the wet etching apparatus 58_{i+q}, and the semiconductor wafer 11 is transferred from the type 2 container to the wet etching apparatus 58_{i+q} through the transfer chamber 57_{i+q} (not shown). In accordance with the recipe transmitted from the apparatus group control server 51, the upper portion of the SiO₂ film 18r is removed by wet etching with dilute hydrofluoric acid (HF) solution to bury the device isolation insulating film 18 in the deep recesses of the device isolation groove 31 as shown in FIG. 14. Furthermore, the Si₃N₄ film (CMP stopper layer) 14 is removed by wet etching with phosphoric acid (H₃PO₄) solution as shown in FIG. 15. As a result, by the removal of the upper portion of the SiO₂ film 18r, the upper portion of the side face of the floating electrode 13 is exposed e.g. about 100 nm from the upper face of the device isolation insulating film 18 as shown in FIG. 15. The semiconductor wafer 11 as shown in FIG. 15 is subjected to prescribed washing, which is a preprocessing of reduced-pressure CVD on the interelectrode insulating film. Then the semiconductor wafer 11 is transferred to the unloader 56_{i+q} (not shown) through the transfer chamber 57_{i+q}. Inside the unloader 56_{i+q}, the semiconductor wafer 11 is stored in the type 2 container. The lid of the type 2 container is closed. Then the type 2 container is robot-transported via the transport rail 54 and the interbay container transport rail 50 to the loader 55ᵢ₊₁₂ of the interelectrode insulating film reduced-pressure CVD apparatus 58ᵢ₊₁₂ shown in FIG. 1.

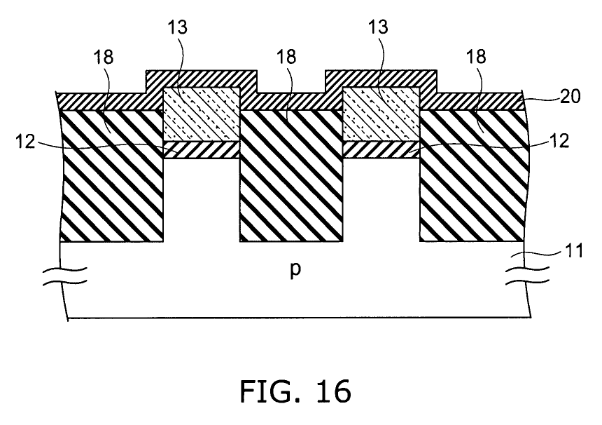

(o) The lid of the type 2 container is opened in the loader 55ᵢ₊₁₂ of the interelectrode insulating film reduced-pressure CVD apparatus 58ᵢ₊₁₂, and the semiconductor wafer 11 is transferred from the type 2 container to the interelectrode insulating film reduced-pressure CVD apparatus 58ᵢ₊₁₂ through the transfer chamber 57ᵢ₊₁₂. In accordance with the recipe transmitted from the apparatus group control server 51, as shown in FIG. 16, an interelectrode insulating film 20 is deposited on the floating electrode 13 and the device isolation insulating film 18. During the process of depositing an interelectrode insulating film 20, the apparatus group control server 51 shown in FIG. 1 uses the product information to derive the next process, which is a polysilicon CVD process of forming a second conductive layer 22p serving as a control electrode 22. Furthermore, the apparatus group control server 51 uses the product information to determine that the device isolation insulating film 18 made of SiO₂ film transformed by thermal oxidation from the PSZ film 18q is covered with the interelectrode insulating film 20 during the transport from the interelectrode insulating film reduced-pressure CVD apparatus 58ᵢ₊₁₂ to the polysilicon reduced-pressure CVD apparatus 58ᵢ₊₂, and hence that the transport is to be associated with a “non-specific interprocess transport path”. As a result, the apparatus group control server 51 generates container information for the “non-specific interprocess transport path” and communicates it to the interelectrode insulating film reduced-pressure CVD apparatus 58ᵢ₊₁₂ to instruct the type change of the closed-type transport container 60. As a result, the empty type 2 container is transported from the loader 55ᵢ₊₁₂ of the interelectrode insulating film reduced-pressure CVD apparatus 58ᵢ₊₁₂ via the transport rail 54 to the container discrimination/selection apparatus 53a, 53b shown in FIG. 1. The container discrimination/selection apparatus 53a, 53b uses the signal (container identification information) from the RF tag 64 to select, in the temporary container cabinet 52a, 52b shown in FIG. 1, a type 1 container. That is, under the command from the apparatus group control server 51, the container discrimination/selection apparatus 53a, 53b selects a type 1 container and moves the selected type 1 container to the unloader 56ᵢ₊₁₂ of the interelectrode insulating film reduced-pressure CVD apparatus 58ᵢ₊₁₂ via the transport rail 54. The semiconductor wafer 11 with the device isolation insulating film 18 covered with the interelectrode insulating film 20 as shown in FIG. 16 is transferred to the unloader 56ᵢ₊₁₂ through the transfer chamber 57ᵢ₊₁₂. Inside the unloader 56ᵢ₊₁₂, the semiconductor wafer 11 is stored in the type 1 container. The lid of the type 1 container is closed. Then the type 1 container is robot-transported via the transport rail 54 to the loader 55ᵢ₊₂ of the polysilicon reduced-pressure CVD apparatus 58ᵢ₊₂.

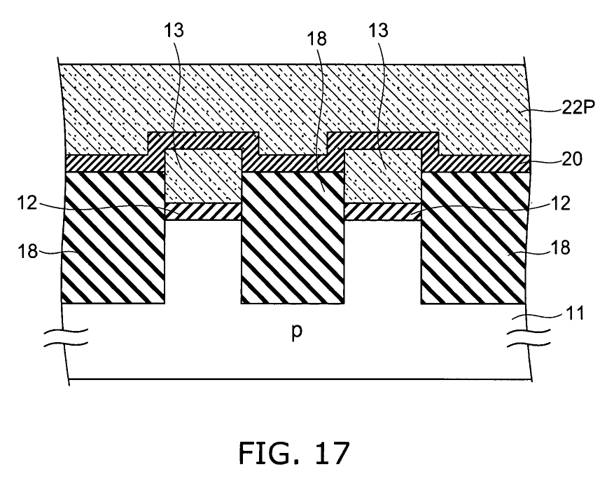

(p) The lid of the type 1 container is automatically opened in the loader 55ᵢ₊₂ of the polysilicon reduced-pressure CVD apparatus 58ᵢ₊₂, and the semiconductor wafer 11 is transferred from the type 1 container to the polysilicon reduced-pressure CVD apparatus 58ᵢ₊₂ through the transfer chamber 57ᵢ₊₂. In accordance with the recipe transmitted from the apparatus group control server 51, as shown in FIG. 17, a second conductive layer 22p serving as a control electrode 22 shown in FIG. 8 is deposited on the interelectrode insulating film 20. For example, a polycrystalline silicon film is deposited on the interelectrode insulating film 20 to a thickness of 10 to 200 nm by reduced-pressure CVD. Then the semiconductor wafer 11 is transferred to the unloader 56ᵢ₊₂ through the transfer chamber 57ᵢ₊₂. Inside the unloader 56ᵢ₊₂, the semiconductor wafer 11 is automatically stored in the type 1 container. The lid of the type 1 container is automatically closed. Then the type 1 container is robot-transported via the transport rail 54 to the loader 55ᵢ₊₄ of the spinner 58ᵢ₊₄.

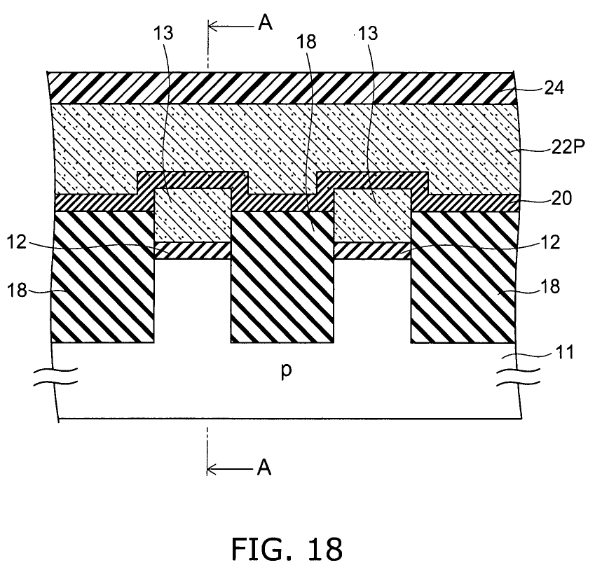

(q) The process by the spinner 58ᵢ₊₄, the subsequent process by the stepper 58ᵢ₊₅, and the further subsequent process by the developing apparatus 58ᵢ₊₆ are similar to the above processes (e) to (g). A photoresist film 24 is applied onto the second conductive layer 22p formed in the polysilicon reduced-pressure CVD apparatus 58ᵢ₊₂, and is patterned by projection exposure by the stepper 58ᵢ₊₅ and by the subsequent developing process by the developing apparatus 58ᵢ₊₆. As a result, as shown in FIG. 18, a pattern of the photoresist film 24 is formed on the second conductive layer 22p. The semiconductor wafer 11 with a pattern of the photoresist film 24 formed thereon, after resist curing, is transferred to the unloader 56ᵢ₊₆ through the transfer chamber 57ᵢ₊₆. Inside the unloader 56ᵢ₊₆, the semiconductor wafer 11 is stored in the type 1 container. The lid of the type 1 container is closed. Then the type 1 container is robot-transported via the transport rail 54 to the loader 55ᵢ₊₇ of the RIE apparatus 58ᵢ₊₇.

(r) The lid of the type 1 container is opened in the loader 55ᵢ₊₇ of the RIE apparatus 58ᵢ₊₇, and the semiconductor wafer 11 is transferred from the type 1 container into the etching chamber of the RIE apparatus 58ᵢ₊₇ through the transfer chamber 57ᵢ₊₇. In accordance with the recipe transmitted from the apparatus group control server 51, the pattern of the photoresist film 24 is used as an etching mask for isolation between cells within a column to selectively etch the second conductive layer 22p, the interelectrode insulating film 20, the first conductive layer 13, and the gate insulating film (tunnel oxide film) 12 until the silicon substrate 11 is exposed, thereby forming a plurality of slit-like cell isolation grooves extending in the row direction (word line direction). As a result, as shown in FIG. 19, memory cell transistors within a cell column are isolated from each other. (The cross-sectional structure of FIG. 19 shows a cross section as viewed along the A-A direction perpendicular to the page of FIG. 18. That is, FIGS. 9 to 18 have been described with reference to the cross section taken parallel to the word lines WL1ₖ, WL2ₖ, . . . , WL32ₖ, WL1ₖ₋₁, . . . shown in FIG. 7 and cutting a particular word line. FIGS. 19 to 22 will be described with reference to a cross section taken parallel to the bit lines BL₂ⱼ₋₁, BL₂ⱼ, BL₂ⱼ₊₁, . . . corresponding to the A-A direction in FIG. 7.) The cell isolation groove allows the floating electrode 13 made of the first conductive layer and the control electrode 22 of each memory transistor within a cell column to be isolated. Although not shown, the select transistor is also isolated from the memory cell transistor by the cell isolation groove in the column direction. After completion of the continuous RIE, the semiconductor wafer 11 is transferred to the unloader 56ᵢ₊₇ through the transfer chamber 57ᵢ₊₇. Inside the unloader 56ᵢ₊₇, the semiconductor wafer 11 is stored in the type 1 container. The lid of the type 1 container is closed. Then the type 1 container is robot-transported via the transport rail 54 to the loader 55ᵢ of the washer 58ᵢ.

(s) The lid of the type 1 container is opened in the loader 55ᵢ of the washer 58ᵢ, and the semiconductor wafer 11 is transferred from the type 1 container to the washer 58ᵢ through the transfer chamber 57ᵢ. In accordance with the recipe transmitted from the apparatus group control server 51, the resist mask 24 is removed. The semiconductor wafer 11 from which the resist mask 24 has been removed is transferred to the unloader 56ᵢ through the transfer chamber 57ᵢ. Inside the unloader 56ᵢ, the semiconductor wafer 11 is stored in the type 1 container. The lid of the type 1 container is closed. Then the type 1 container is robot-transported via the transport rail 54 to the loader 55ᵢ₊₁₃ of the ion implantation apparatus 58ᵢ₊₁₃.

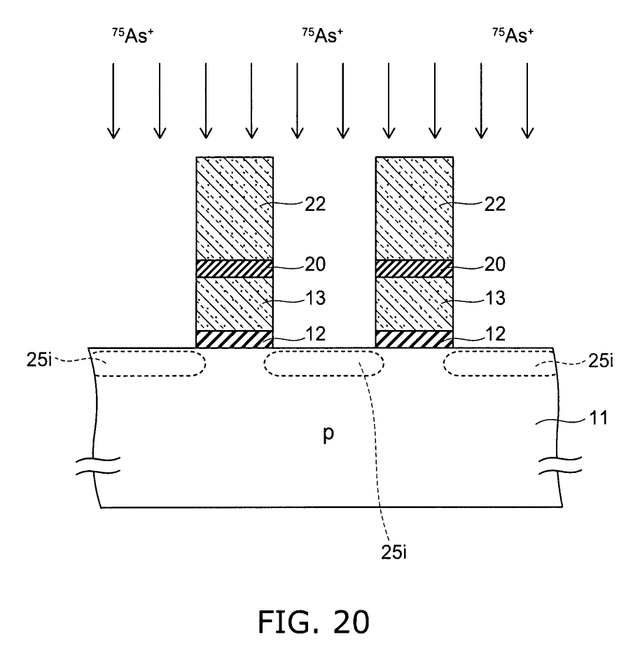

(t) The lid of the type 1 container is automatically opened in the loader 55ᵢ₊₁₃ of the ion implantation apparatus 58ᵢ₊₁₃, and the semiconductor wafer 11 is transferred from the type 1 container to the ion implantation apparatus 58ᵢ₊₁₃ through the transfer chamber 57ᵢ₊₁₃. In accordance with the recipe transmitted from the apparatus group control server 51, as shown in FIG. 20, the laminated structure (12, 13, 20, 22) composed of the gate insulating film (tunnel oxide film) 12, the floating electrode 13, the interelectrode insulating film 20, and the control electrode 22 and isolated from each other by the cell isolation groove is used as a mask to implant n-type dopant ions such as arsenic ions (⁷⁵As⁺) or phosphorus ions (³¹P⁺) into the semiconductor substrate 11 exposed to the cell isolation groove in a self-aligned manner. In FIG. 20, the ion implantation region 25i in the non-activated state is indicated by the dashed line. The semiconductor wafer 11 doped with n-type dopant ions is transferred to the unloader 56ᵢ₊₁₃ through the transfer chamber 57ᵢ₊₁₃. Inside the unloader 56ᵢ₊₁₃, the semiconductor wafer 11 is automatically stored in the type 1 container. The lid of the type 1 container is automatically closed. Then the type 1 container is robot-transported via the transport rail 54 to the loader 55ᵢ₊₁₄ of the annealing furnace 58ᵢ₊₁₄.

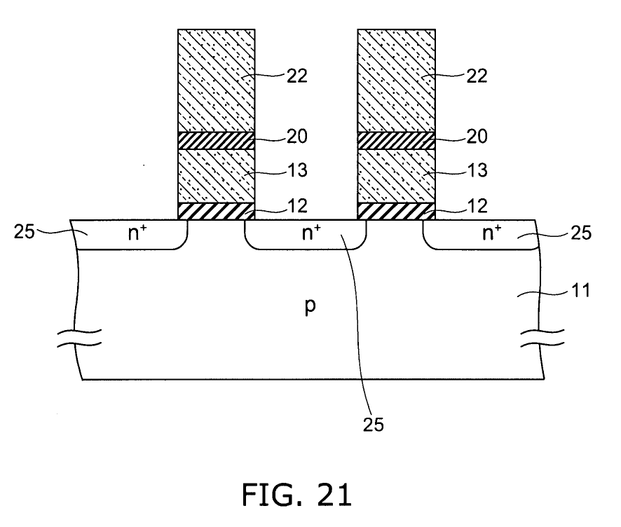

(u) The lid of the type 1 container is automatically opened in the loader 55ᵢ₊₁₄ of the annealing furnace 58ᵢ₊₁₄, and the semiconductor wafer 11 is transferred from the type 1 container to the annealing furnace 58ᵢ₊₁₄ through the transfer chamber 57ᵢ₊₁₄. In accordance with the recipe transmitted from the apparatus group control server 51, activation annealing following ion implantation is performed. As a result, as shown in FIG. 21, a source/drain region 25 is formed in the surface of the semiconductor substrate 11, and thereby each memory transistor is constructed. The semiconductor wafer 11 with the source/drain regions 25 formed therein is transferred to the unloader 56ᵢ₊₁₄ through the transfer chamber 57ᵢ₊₁₄. Inside the unloader 56ᵢ₊₁₄, the semiconductor wafer 11 is automatically stored in the type 1 container. The lid of the type 1 container is automatically closed. Then the type 1 container is robot-transported via the transport rail 54 to the loader 55ᵢ₊₁₅ of the interlayer insulating film CVD apparatus 58ᵢ₊₁₅.

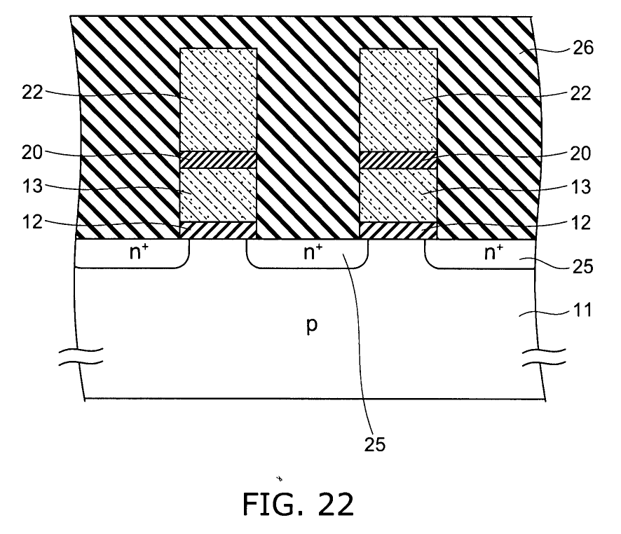

(v) The lid of the type 1 container is automatically opened in the loader 55ᵢ₊₁₅ of the interlayer insulating film CVD apparatus 58ᵢ₊₁₅, and the semiconductor wafer 11 is transferred from the type 1 container to the interlayer insulating film CVD apparatus 58ᵢ₊₁₅ through the transfer chamber 57ᵢ₊₁₅. In accordance with the recipe transmitted from the apparatus group control server 51, an SiOF film is deposited as an interlayer insulating film 26 by the HDP method using difluorofuran (SiH₂F₂) gas, for example. As a result, as shown in FIG. 22, the interlayer insulating film 26 is buried between each pair of memory cell transistors isolated from each other by the cell isolation groove and between the memory cell transistor and the select transistor (not shown). The semiconductor wafer 11 with the interlayer insulating film 26 deposited thereon is transferred to the unloader 56ᵢ₊₁₅ through the transfer chamber 57ᵢ₊₁₅. Inside the unloader 56ᵢ₊₁₅, the semiconductor wafer 11 is automatically stored in the type 1 container. The lid of the type 1 container is automatically closed. Then the type 1 container is robot-transported via the transport rail 54 to the loader 55ᵢ₊₄ of the spinner 58ᵢ₊₄.

(w) The process by the spinner 58ᵢ₊₄, the subsequent process by the stepper 58ᵢ₊₅, and the further subsequent process by the developing apparatus 58ᵢ₊₆ are similar to the above processes (e) to (g). A new photoresist film is applied on the entire surface, and then the new photoresist film is patterned using the conventional photolithography technique. The new photoresist film is used as an etching mask to open a via hole (contact hole) between the two select transistors by the RIE apparatus 58ᵢ₊₇. The contact hole is filled with a contact plug made of tungsten or other conductor by a sputtering apparatus, a vacuum evaporation apparatus, and a metal CVD apparatus in the adjacent bay area, not shown. Furthermore, a metal film (conductor film) is deposited by these sputtering apparatus, vacuum evaporation apparatus, and metal CVD apparatus. Then the metal film (conductor film) is patterned by the photolithography technique similar to that used in the above processes (e) to (g) and RIE similar to that used in the process (h) (or using the damascene technique) to form the interconnect of bit lines 27 on the interlayer insulating film 26 as shown in FIG. 8. Thus a semiconductor memory device according to the embodiment of the invention is completed. Although not shown in FIG. 8, as with conventional processes for manufacturing NAND nonvolatile semiconductor memory devices (flash memories), an insulating film such as silicon nitride film or polyimide film may be formed as a passivation film on the interconnect of bit lines 27.

The robot-transport manufacturing method according to the embodiment of the invention illustrated above in (a) to (w) can prevent the influence of cross-contamination via the closed-type transport container caused by contaminating factors (NH₃) that occurs during the transport associated with the process of applying a silazane perhydride polymer solution, the baking process following this applying process, and the oxidation process following this baking process. Hence, in particular, shape anomaly is eliminated in the fine pattern of the photoresist film in the photolithography process. Thus the semiconductor manufacturing line composed of numerous manufacturing apparatuses (semiconductor manufacturing apparatuses) can introduce the minienvironment technology using closed-type transport containers, and thereby NAND nonvolatile semiconductor memory devices (flash memories) with high precision and quality can be manufactured at high manufacturing yield.

In the above robot-transport manufacturing method, during the process of removing the resist mask 15 in the washer 58ᵢ, the apparatus group control server 51 determines that the next interprocess transport path to the silazane perhydride coater 58ᵢ₊₈ is to be a “specific interprocess transport path”, generates container information for the “specific interprocess transport path”, and instructs the washer 58ᵢ on the type change of the closed-type transport container 60. Furthermore, during the process of depositing an interelectrode insulating film 20 in the interelectrode insulating film reduced-pressure CVD apparatus 58ᵢ₊₁₂, the apparatus group control server 51 determines that the next interprocess transport path to the polysilicon CVD process for the second conductive layer 22p is to be a “non-specific interprocess transport path” and instructs the interelectrode insulating film reduced-pressure CVD apparatus 58ᵢ₊₁₂ on the type change of the closed-type transport container 60. However, this is for illustrative purpose only. For example, before starting the lot processing in accordance with the method for manufacturing a NAND nonvolatile semiconductor memory device described above in (a) to (w), the apparatus group control server 51 may predetermine the container information for all the interprocess transport paths for the processes including (a) to (w), and preprogram the transport type of the closed-type transport container for every interprocess transport path on the basis of the predetermined container information. More specifically, a program regarding the container information may be stored in a program memory device, and the apparatus group control server 51 may send a notification of the container information and an instruction of the type change to the associated manufacturing apparatuses 58ᵢ, 58ᵢ₊₁, 58ᵢ₊₂, 58ᵢ₊₃, . . . on the basis of the program stored in the program memory device. Thus the closed-type transport containers 60 may be successively exchanged along the required interprocess transport paths.

In the above process (v) of burying the interlayer insulating film 26 between each pair of memory cell transistors isolated from each other by the cell isolation groove and between the memory cell transistor and the select transistor, the silazane perhydride coater 58ᵢ₊₈, the silazane perhydride baking apparatus 58ᵢ₊₉, and the PSZ film oxidation apparatus 58ᵢ₊₁₀ may be used to bury PSZ film in the cell isolation groove. In this case, another occurrence of the type change from the type 1 container to the type 2 container and a subsequent type change from the type 2 container to the type 1 container are to be added.

The flow of the method for manufacturing a NAND nonvolatile semiconductor memory device (flash memory) described above in (a) to (w) is presented for convenience of describing a robot-transport manufacturing method according to the embodiment of the invention. In practice, before the ion implantation process shown in FIG. 20, an underlying film made of a silicon oxide film having a thickness of about 6 nm may be formed on the surface of the semiconductor substrate 11, the sidewall of the control electrode (CVD control electrode) 22 exposed to the cell isolation groove, and the sidewall of the floating electrode (13, 19) exposed to the cell isolation groove by heat treatment at about 800° C. for about 120 seconds in nitrogen atmosphere, followed by heat treatment at about 1000° C. in oxidizing atmosphere. Subsequently, ion implantation as shown in FIG. 20 may be performed through this underlying film. Various other processes can be added. In particular, the above process (w) is described by simplifying the metallization process. However, it is understood that, in practice, a plurality of processes not described may be used to perform the metallization process for multilayer interconnection.

### Other Embodiments

The invention has been described with reference to the above embodiment. However, the description and drawings constituting part of this disclosure should not be understood as limiting the present invention. Various alternative embodiments, examples, and practical applications will be apparent to those skilled in the art from this disclosure.

The foregoing embodiment is described with reference to a NAND nonvolatile semiconductor memory device (flash memory), and a method for manufacturing the same is illustratively described. However, the invention is similarly applicable to AND or DINOR flash memories other then NAND flash memories, and further applicable to various other semiconductor memory devices such as DRAM and SRAM. Moreover, it is understood that the invention is also applicable to manufacturing various semiconductor devices such as logic integrated circuits.

Semiconductor device manufacturing may be a typical example of technical fields requiring cleanliness. However, besides semiconductor device manufacturing, there is also a growing demand for cleanliness in methods for manufacturing liquid crystal devices, magnetic recording media, optical recording media, thin-film magnetic heads, superconducting devices, acoustoelectric conversion devices, biotechnology products, and chemical agents. It will be readily understood from the above description that the invention is applicable to the operation of closed-type transport containers in the local clean technology (robot-transport manufacturing method) of these various fields and local clean robot-transport plants based thereon.

The foregoing embodiment is described with reference to a NAND nonvolatile semiconductor memory device (flash memory), and a description is illustratively made of the case where ammonia (NH₃) derived from silazane perhydride reacts with the material of the closed-type transport container to cause cross-contamination. However, a process of burying a solution of polysilasilazane given by the following formula (2), for example, in the device isolation groove by spin coating may also cause cross-contamination due to NH₃ in the associated interprocess transport paths. 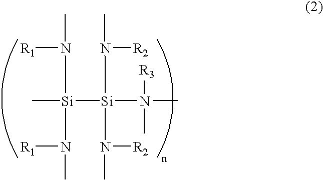
Hence the invention is not limited to manufacturing processes based on silazane perhydride polymer solution.

Furthermore, besides NH₃, contaminating factors (chemicals) reacting with the material of the closed-type transport container to cause cross-contamination also include nitrogen oxides (NOₓ), sulfur oxides (SOₓ), halogens such as chlorine (Cl) and fluorine (F), amines such as monoethanolamine (MEA), phthalate esters, and siloxane compounds. Cross-contamination by these substances may cause problems depending on technical fields, product specifications, and the contamination levels. In some cases, problems caused by water associated with the washing process and particles associated with the CMP process may be also contemplated depending on technical fields and product specifications. Hence the invention should not be construed as being limited by the above embodiment.

In practical applications to these various fields, there may be a plurality of kinds of “specific interprocess transport paths”, and two kinds of specific interprocess transport paths may partially overlap each other depending on product specifications. More specifically, closed-type transport containers used in the example described above are grouped into two transport types: closed-type transport containers of transport type 2 for transporting semiconductor wafers on the predetermined specific interprocess transport paths and closed-type transport containers of transport type 1 for transporting semiconductor wafers on interprocess transport paths other than these specific interprocess transport paths. However, if there are a plurality of kinds of specific interprocess transport paths, closed-type transport containers of three or more transport types can be naturally used as a logical conclusion.

Furthermore, the “specific interprocess transport paths” can be defined even if the contaminating factors are not identified. In particular, in gate oxidation, which may cause contamination problems due to heavy metals and alkali ions, the path from the washing apparatus 58ᵢ for the preprocessing of gate oxidation to the gate oxidation apparatus 58ᵢ₊₁ may be defined as a “specific interprocess transport path”. Moreover, the closed-type transport containers used on the specific interprocess transport path of gate oxidation may be subjected to special treatment such as intentional injection of chlorine gas into the inner wall thereof.

Thus it is understood that the present invention includes various embodiments not described herein. Therefore the scope of the invention is to be defined only by the elements recited in the accompanying claims, which are supported by the above description.

1. A local clean robot-transport plant comprising:
a plurality of manufacturing apparatuses;
a plurality of closed-type transport containers, each closed-type transport container storing and transporting an intermediate product of manufacturing processes along a plurality of interprocess transport paths defined among the plurality of manufacturing apparatuses in accordance with a flow of the manufacturing processes;
a container discrimination/selection apparatus configured to discriminate and select the closed-type transport container of transport type 1 and the closed-type transport container of transport type 2, respectively, from among the plurality of closed-type transport containers;
an apparatus group control server configured to collectively control operation of the plurality of manufacturing apparatuses and the container discrimination/selection apparatus to move the closed-type transport container of transport type 2 to a specific interprocess transport path and to move the closed-type transport container of transport type 1 to the interprocess transport path other than the specific interprocess transport path.

2. The local clean robot-transport plant according to claim 1, further comprising: a temporary container cabinet configured to store the plurality of closed-type transport containers, wherein
the container discrimination/selection apparatus discriminates and selects the closed-type transport container of transport type 1 and the closed-type transport container of transport type 2, respectively, from among the plurality of closed-type transport containers stored in the temporary container cabinet.

3. The local clean robot-transport plant according to claim 1, wherein
the plurality of closed-type transport containers each include container identification information output means configured to output container identification information including at least type identification information that identifies whether the closed-type transport container is of the transport type 1 or of the transport type 2, and
the container discrimination/selection apparatus uses the container identification information outputted by the container identification information output means to discriminate between the closed-type transport container of transport type 1 and the closed-type transport container of transport type 2, respectively, from among the plurality of closed-type transport containers stored in the temporary container cabinet.

4. The local clean robot-transport plant according to claim 3, wherein the plurality of manufacturing apparatuses each include a container identification information input means configured to discriminate the closed-type transport container of transport type 1 and the closed-type transport container of transport type 2, respectively, from among the plurality of closed-type transport containers.

5. The local clean robot-transport plant according to claim 3, wherein the container identification information output means is one of RF tag and two-dimensional codes.

6. The local clean robot-transport plant according to claim 1, wherein the specific interprocess transport path is an interprocess transport path on which cross-contamination via the closed-type transport containers caused by a contaminating factor due to a specific process.

7. The local clean robot-transport plant according to claim 6, wherein the contaminating factor includes NH₃.

8. The local clean robot-transport plant according to claim 1, wherein the specific interprocess transport path is an interprocess transport path on which the intermediate product including an exposed silazane perhydride or polysilasilazane is transported.

9. The local clean robot-transport plant according to claim 1, wherein
the intermediate product is transported to the manufacturing apparatus configured to apply a coating material containing silazane perhydride or polysilasilazane by using the closed-type transport container of transport type 1 to transport,
the transport the intermediate product is transported to the manufacturing apparatuses configured to perform a baking process following the application of the coating material, an oxidation process following the baking process, and a process of forming a thin film made of material other than the silazane perhydride or polysilasilazane on an oxide film formed by the oxidation process by using the closed-type transport container of transport type 2; and
the intermediate product is transported from the manufacturing apparatus used for the process of forming a thin film to the manufacturing apparatuses for subsequent processes by using the closed-type transport container of transport type 1 to transport.

10. A robot-transport manufacturing method based on a plurality of manufacturing apparatuses controlled by an apparatus group control server, an intermediate product of manufacturing processes being stored in a plurality of closed-type transport containers and transported along a plurality of interprocess transport paths defined among the plurality of manufacturing apparatuses in accordance with a flow of the manufacturing processes, the method comprising:
under control of the apparatus group control server, using the closed-type transport container of transport type 2 only on a specific interprocess transport path, and using only the closed-type transport container of transport type 1 on the interprocess transport paths other than the specific interprocess transport path.

11. The robot-transport manufacturing method according to claim 10, wherein an interprocess transport path on which cross-contamination via the closed-type transport containers caused by a contaminating factor due to a specific process is defined as the specific interprocess transport path.

12. The robot-transport manufacturing method according to claim 11, wherein the contaminating factor includes NH₃.

13. The robot-transport manufacturing method according to claim 10, wherein
the plurality of closed-type transport containers each include container identification information output means configured to output container identification information including at least type identification information that identifies whether the closed-type transport container is of the transport type 1 or of the transport type 2, and
the container identification information is electromagnetically or optically read to discriminate between the closed-type transport container of transport type 1 and the closed-type transport container of transport type 2.

14. The robot-transport manufacturing method according to claim 10, wherein the specific interprocess transport path is an interprocess transport path on which the intermediate product including an exposed silazane perhydride or polysilasilazane is transported.

15. The robot-transport manufacturing method according to claim 10, wherein
the intermediate product is transported to the manufacturing apparatus configured to apply a coating material containing silazane perhydride or polysilasilazane by using the closed-type transport container of transport type 1 to transport,
the transport the intermediate product is transported to the manufacturing apparatuses configured to perform a baking process following the application of the coating material, an oxidation process following the baking process, and a process of forming a thin film made of material other than the silazane perhydride or polysilasilazane on an oxide film formed by the oxidation process by using the closed-type transport container of transport type 2; and
the intermediate product is transported from the manufacturing apparatus used for the process of forming a thin film to the manufacturing apparatuses for subsequent processes by using the closed-type transport container of transport type 1 to transport.

16. A robot-transport manufacturing method configured to manufacture intended industrial products, an intermediate product of manufacturing processes being stored in closed-type transport containers and transported along a plurality of interprocess transport paths defined among a plurality of manufacturing apparatuses in accordance with a flow of the manufacturing processes, the method comprising:
using the closed-type transport container of transport type 2 only on a specific interprocess transport path; and
using only the closed-type transport container of transport type 1 on the interprocess transport paths other than the specific interprocess transport path.

17. The robot-transport manufacturing method according to claim 16, wherein an interprocess transport path on which cross-contamination via the closed-type transport containers caused by a contaminating factor due to a specific process is defined as the specific interprocess transport path.

18. The robot-transport manufacturing method according to claim 17, wherein the contaminating factor includes NH₃.

19. The robot-transport manufacturing method according to claim 16, wherein the specific interprocess transport path is an interprocess transport path on which the intermediate product including an exposed silazane perhydride or polysilasilazane is transported.

20. The robot-transport manufacturing method according to claim 16, wherein
the intermediate product is transported to the manufacturing apparatus configured to apply a coating material containing silazane perhydride or polysilasilazane by using the closed-type transport container of transport type 1 to transport,
the transport the intermediate product is transported to the manufacturing apparatuses configured to perform a baking process following the application of the coating material, an oxidation process following the baking process, and a process of forming a thin film made of material other than the silazane perhydride or polysilasilazane on an oxide film formed by the oxidation process by using the closed-type transport container of transport type 2; and
the intermediate product is transported from the manufacturing apparatus used for the process of forming a thin film to the manufacturing apparatuses for subsequent processes by using the closed-type transport container of transport type 1 to transport.
